(19) United States
(12) Patent Application Publication
(10) Pub. No.: US 2007/0024168 A1
(43) Pub. Date: Feb. 1, 2007

(54) Organic electroluminescent element and organic electroluminescent display device

(75) Inventors: Kazuki Nishimura, Kumano-city (JP); Yuji Hamada, Heguri-Cho (JP)

Correspondence Address: NDQ&M WATCHSTONE LLP, 1300 EYE STREET, NW, 400 EAST TOWER, WASHINGTON, DC, 20005, US

(73) Assignee: Sanyo Electric Co., Ltd., Moriguchi-City (JP)

(21) Appl. No.: 11/494,618

(22) Filed: Jul. 28, 2006

(30) Foreign Application Priority Data
Jul. 29, 2005 (JP) 2005-221105
Nov. 30, 2005 (JP) 2005-345887
Mar. 27, 2006 (JP) 2006-085321

(51) Int. Cl. H01L 51/52; H01L 51/54; H05B 33/12

(52) U.S. Cl. 313/110; 428/690; 428/917; 313/504; 313/506; 313/112; 257/98; 257/E51.022

(57) ABSTRACT

The invention provides an organic electroluminescent element comprising a cathode, an anode, a plurality of light emitting units layered and arranged between the cathode and the anode via an intermediate unit, a cavity adjustment layer formed between the light emitting unit nearest to the anode and the anode, and an electron extracting layer formed adjacently to the cavity adjustment layer in the light emitting unit side and is characterized in that the film thickness of the cavity adjustment layer is adjusted to adjust the optical distance from the light emitting position of each light emitting unit to the anode.

### BACKGROUND OF THE INVENTION

1. Field of the Invention

The present invention relates to an organic electroluminescent element and an organic electroluminescent display device.

2. Description of the Related Art

An organic electroluminescent element (organic EL element) has been actively developed from a viewpoint of application to display and illumination. Principle for driving an organic EL element is as follows; That is, a hole and an electron are injected through an anode and a cathode, respectively, these are transported in an organic thin film, and recombined in a light emitting layer to generate the excited state, and light emitting is obtained from this excited state. In order to enhance a light emitting efficiency, it is necessary to inject a hole and an electron effectively, and transport them in an organic thin film. However, since movement of a carrier in an organic EL element undergoes restriction due to an energy barrier between an electrode and an organic thin film, and low carrier mobility in an organic thin film, improvement in a light emitting efficiency is limited.

On the other hand, as another method of improving a light emitting efficiency, there is a method of layering a plurality of light emitting layers. For example, by layering an orange light emitting layer and a blue light emitting layer in a complementary color relationship so that they are directly contacted, a higher light emitting efficiency than that of the case of a monolayer can be obtained in some cases. For example, in the case where a light emitting efficiency of a blue light emitting layer is 10 cd/A, and a light emitting efficiency of an orange light emitting layers is 8 cd/A, when these are layered to form a white light emitting element, a light emitting efficiency of 15 cd/A is obtained.

However, in the case of layering a plurality of light emitting layers, since a plurality of light emitting areas exist, there occurs a problem that the cavity adjustment becomes difficult. That is, there are light emitted to the anode side and light emitted to the cathode side as the light from the light emitting layers and since the cathode is generally formed to be a reflectively electrode, the light emitted to the cathode side is reflected by the cathode and emitted to the anode side. In such a manner, in an organic EL element, since optical interference is caused due to the double paths, it becomes very important in terms of the design to adjust the optical distance in the element and increase the quantity of the light to be emitted from the element.

In Japanese Patent Application Laid-Open (JP-A) Nos. 2003-272860 and 2004-342614, with respect to an organic EL element in which a plurality of light emitting units are laminated, the optical film thickness is adjusted independently for each light emitting unit so as to adjust the above-mentioned cavity. However, there is a problem that when the thickness of the layers composing the each light emitting unit is adjusted, the carrier balance in each light emitting unit is changed to lead to the considerable alteration of the properties of the elements and impossibility of obtaining desired properties.

Further, in an organic EL element, a charge transporting layer and a charge injecting layer are generally formed for transporting a hole or an electron between an electrode and a light emitting layer.

JP-A No. 2003-151776 proposes that in the structure composed by layering a hole injecting layer, a hole transporting layer, an electron trapping layer, a light emitting layer, and an electron transporting layer from the anode side to the cathode side, the minimum energy level of the conduction band of a mother material of the electron trapping layer is lowered than those of the mother material of the hole transporting layer and the mother material of the light emitting layer. Accordingly, deterioration of the mother material of the hole transporting layer in the anode side is prevented.

JP-A No. 2004-207000 proposes insertion of a mixed layer of a mixture of materials composing neighboring hole transporting layers in an interface of the neighboring two hole transporting layers and describes that the adhesion property of the neighboring two charge transporting layers is improved and the light emitting efficiency and brightness life are improved.

In JP-A No. 2003-229269, it is proposed that a cathode buffer layer and an electron transporting layer are reciprocally layered at least two or more times between a cathode and a light emitting layer to control the electron transporting efficiency.

Conventionally, for a hole transporting layer, a tertiary arylamine type material such as NPB (N,N′-di(naphthacen-1-yl)-N,N′-diphenylbenzidine) has been used, however if the film thickness of the hole transporting layer of NPB or the like is made thick to adjust a cavity, since the carrier mobility of the hole transporting material, NPB or the like, is low, there occurs a problem that the driving voltage is increased. Accordingly, it is required to provide an electron structure of an organic EL element in which the driving voltage is lowered even if the film thickness of NPB or the like is made thick.

Also, there is another problem in the organic EL display that the organic EL display has a visible angle dependency, that is, the color tone of an image is slightly changed in the front view or in a slanting view. The visible angle dependency of the organic EL display is not so much significant, different from that in the case of a liquid crystal display in which the image is reversed if the image is observed from a slanting angle. The reasons for that are because the refraction index difference is wide between an organic layer and an inorganic layer (e.g., an ITO film) composing the organic EL element and because the cathode of an organic EL element works like a mirror to cause an optical interference in an element. The slight visible angle dependency lowers the display quality of the organic EL display and therefore, it is preferable to suppress the dependency. However, any effective manner to sufficiently lower the visible angle dependency has been proposed so far.

On the other hand, the organic EL display is expected to be a display for a mobile appliance and is required to save power consumption and prolong the life. The inventors of the invention have found that the electric power consumption can be saved and the life can be prolonged by layering a plurality of light emitting layers via an intermediate unit (reference to JP-A No. 2006-49396). However, this patent document contains no description of the visible angle dependency.

JP-A No. 2003-272860 discloses lamination of a plurality of light emitting layers and describes that the brightness and the light emitting efficiency are improved by adjusting the distance of a reflection electrode and a light source nearer to the reflection electrode to be ¼λ and the distance of the reflection electrode and a light source remoter from the reflection electrode to be ¾λ in the two light sources. The light intensity to the front face direction is certainly increased to the maximum by setting as described above, however the intensity is contrarily decreased in a slanting direction (e.g. at 60°) and the visible angle dependency becomes significant and the display quality is considerably lowered.

Improved Synthesis of 1,4,5,8,9,12-Hexaazatriphenylenehexacarboxylic acid, SYNTHESIS, April, 1994, p. 378-380, discloses a synthetic method of hexaazatriphenylene derivative to be used in the invention.

### SUMMARY OF THE INVENTION

A first purpose of the invention is to provide an organic EL element comprising a plurality of layered light emitting units and in which the cavity is easily adjusted without changing the film thickness in the respective light emitting units and an organic EL display device employing the organic EL element.

A second purpose of the invention is to provide an organic EL element and an organic EL display device in which the cavity can be adjusted and which have a high light emitting efficiency; can lower the driving voltage; and can improve the reliability.

A third purpose of the invention is to provide an organic EL element whose visible angle dependency can be lowered.

### FIRST ASPECT OF THE INVENTION

An organic EL element of the invention comprises a cathode, an anode, and a plurality of light emitting units arranged between the cathode and the anode via an intermediate unit and is characterized in that the organic EL element is further provided with a cavity adjustment layer for adjusting the optical distance from the light emitting positions of the respective light emitting units to the anode and an electron extracting layer formed adjacent to the cavity adjustment layer in a light emitting unit side between the light emitting unit nearest to the anode and the anode.

In the invention, the cavity adjustment layer is formed between the light emitting unit nearest to the anode and the cathode and the optical distance from the light emitting positions of the respective light emitting units to the anode can be adjusted by adjusting the film thickness of the cavity adjustment layer. Therefore, without changing the film thickness of the respective light emitting units, the cavity can be adjusted. Accordingly, without significantly changing the element properties, the cavity can be adjusted. Consequently, according to the invention, optical interference between an optical path in the case where light is emitted from the light emitting positions of respective light emitting units to side of the anode, which is a transparent electrode, and an optical path in the case where light is emitted to the cathode and reflected by the cathode, which is a reflective electrode, to the anode side can be adjusted and the light extraction quantity from the element can be increased.

In the invention, the electron extracting layer is formed adjacently to the cavity adjustment layer in the light emitting unit side in the cavity adjustment layer. The electron extracting layer extracts an electron from the neighboring layer in the light emitting unit side and supplies a hole generated thereby to the light emitting unit side and the extracted electron to the anode side. The layer neighboring to the electron extracting layer may be a layer which is contained in a light emitting unit or a layer which is not contained in a light emitting unit. That is, the electron extracting layer may be adjacent to the light emitting units or may be adjacent to a layer other than the light emitting unit.

Formation of the electron extracting layer in the light emitting unit side of the cavity adjustment layer makes it possible to prolong the life of the organic EL element.

In the invention, the optical distance from the light emitting positions from the respective light emitting units to the anode is adjusted by adjusting the film thickness of he cavity adjustment layer. Therefore, a material composing the cavity adjustment layer is preferable to be a material which scarcely affects the light emitting property by the alteration of the film thickness. Generally, if the film thickness of an organic layer composing the organic EL element becomes thicker, the driving voltage may be increased higher and the light emitting efficiency may be decreased more. In terms of suppression of such an effect, the material to be used for composing the cavity adjustment layer in the invention is preferably a material having a carrier mobility of 1×10⁻⁶ cm²/Vs or higher and more preferably a material having a carrier mobility of 1×10⁻⁴ cm²/Vs or higher.

The cavity adjustment layer in the invention is preferable to be formed using a hole transporting material and accordingly the hole mobility is preferably 1×10⁻⁶ cm²/Vs or higher and more preferably 1×10⁻⁴ cm²/Vs or higher. The carrier mobility can be measured by Time of Flight method.

In order to output the light outside from the light emitting units without loss, the cavity adjustment layer of the invention is preferable to have a refraction index in a range from 1.6 to 1.8 in consideration of the conformity with other organic layers. The refraction index can be measured, for example, by forming a thin film, an object to be measured, with a thickness of 100 nm on a silicon substrate and carrying out the measurement by using an ellipsometer. As a light source of the ellipsometer, for example, a He—Ne laser with an output of 1 mW (wavelength of 632.8 nm) can be employed.

The material composing the cavity adjustment layer in the invention is preferably a material which can transmit 50% or more visible light with wavelength in a range from 400 nm to 700 nm in the case where the thickness is 1 μm. Accordingly, light from the respective light emitting units is prevented from absorption in the cavity adjustment layer and therefore from considerable attenuation.

The cavity layer in the invention, as described above, can be formed using, for example, a hole transporting material. As the hole transporting material may be an arylamine type hole transporting material.

In the invention a second electron extracting layer may be formed adjacently to the cavity adjustment layer in the anode side. The heat resistance and the light fastness of the organic EL element can be improved by forming the second electron extracting layer in the anode side.

The electron extracting layer in the invention may be formed, for example, using a pyrazine derivative defined by the following structural formula: 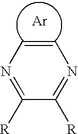
wherein Ar denotes an aryl group; R denotes hydrogen; an alkyl, an alkyloxy, or an dialkylamine group having 1 to 10 carbon atoms; or F, Cl, Br, I, or CN.

In the invention, more preferably, the electron extracting layer may be formed using a hexaazatriphenylene derivative defined by the following structural formula: 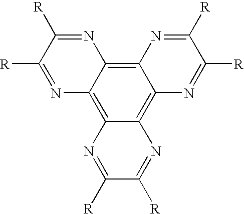
wherein R denotes hydrogen; an alkyl, an alkyloxy, or an dialkylamine group having 1 to 10 carbon atoms; or F, Cl, Br, I, or CN.

In the organic EL element of the invention, a plurality of light emitting units are formed between a cathode and an anode. These light emitting units are layered via an intermediate unit. It is preferable for each intermediate unit to comprise an electron extracting layer for extracting an electron from an adjacent layer adjoining the cathode side and an electron injecting layer adjacent to the anode side in the electron extracting layer. Also, it is preferable that the absolute value of an energy level |LUMO (A)| of the lowest unoccupied molecular orbital (LUMO) of the electron extracting layer and the absolute value of an energy level |HOMO (B)| of the highest occupied molecular orbital (HOMO) of the adjacent layer are in the relationship of |HOMO (B)|−|LUMO (A)|≦1.5 eV, and that the absolute value of an energy level |LUMO (C)| of the lowest unoccupied molecular orbital (LUMO) or the absolute value of the work function |WF (C)| of the electron injecting layer is lower than |LUMO (A)|.

An intermediate unit supplies a hole generated by extraction of an electron from an adjacent layer by the electron extracting layer formed in the intermediate unit to the light emitting unit positioned in the cathode side and, at the same time, supplies the extracted electron to the light emitting unit positioned in the anode side via the electron injecting layer.

Hereinafter, in the explanation of the intermediate units, the light emitting unit positioned in the cathode side is called as the first light emitting unit and the light emitting unit positioned in the anode side is called as the second light emitting unit.

As described above, it is preferable that the absolute value of the energy level |HOMO (B)| of HOMO of the adjacent layer and the absolute value of the energy level |LUMO (A)| of LUMO of the electron extracting layer are in the relationship of |HOMO (B)|−|LUMO (A)|≦1.5 eV and that the energy level of LUMO of the electron extracting layer is an approximate value to the energy level of the HOMO of the adjacent layer, in the intermediate unit. Accordingly, the electron extracting layer can extract an electron from the adjacent layer. Owing to the extraction of an electron from the adjacent layer, a hole is generated in the adjacent layer. In the case where the adjacent layer is formed in the first light emitting unit, a hole is generated in the first light emitting unit. In the case where the adjacent layer is formed between the electron extracting layer and the first light emitting unit; that is, the adjacent layer is formed in the intermediate unit; a hole generated in the adjacent layer is supplied to the first light emitting unit. The hole supplied to the first light emitting unit is recombined with an electron from the cathode and accordingly, the first light emitting unit emits light.

On the other hand, the electron extracted by the electron extracting layer moves to the electron injecting layer and is supplied to the second light emitting unit from the electron injecting layer and recombined with the hole supplied from the anode and accordingly, the second light emitting unit emits light.

In the intermediate unit, to extract the electron from the adjacent layer by the electron extracting layer, it is preferable that the energy level of LUMO of the electron extracting layer is closer to the energy level of HOMO of the adjacent layer than the energy level of LUMO of the adjacent layer. That is, the absolute value of the energy level |LUMO (B)| of LUMO of the adjacent layer is preferable to satisfy the following relationship:
|HOMO (B)|−|LUMO (A)|≦|LUMO (A)|−|LUMO (B)|.

Also, since the absolute value of the energy level of LUMO of the material to be used for the electron extracting layer is generally smaller than the absolute value of the energy level of HOMO of the adjacent layer, the absolute values of the respective energy levels in this case are expressed as the following formula:
0 eV<|HOMO (B)|−|LUMO (A)|≦1.5 eV.

The absolute value of the energy level |LUMO (C)| of LUMO or the absolute value of the work function |WF (C)| of the electron injecting layer is preferable to be lower than the absolute value of the energy level |LUMO (A)| of LUMO of the electron extracting layer and accordingly, the electron extracted from the electron extracting layer moves to the electron injecting layer and is supplied to the second light emitting unit via the electron injecting layer.

It is preferable that an electron transporting layer is formed between the electron injecting layer in the intermediate unit and the second light emitting unit. The absolute value of the energy level |LUMO (D)| of LUMO of the electron transporting layer is preferable to be lower then the absolute value of the energy level |LUMO (C)| of LUMO or the absolute value of the work function |WF (C)| of the electron injecting layer. In the case where the electron transporting layer is formed, the electron which moves to the electron injecting layer is supplied to the second light emitting unit via the electron transporting layer. Accordingly, the intermediate unit supplies the electron which the electron extracting layer extracts to the second light emitting unit via the electron injecting layer and the electron transporting layer.

The electron extracting layer in the intermediate unit may be formed using the material same as the material for the electron extracting layer formed adjoining the above-mentioned cavity adjustment layer of the invention. That is, the layer may be formed using a pyrazine derivative defined by the above-mentioned structural formula or more preferably using a hexaazatriphenylene derivative defined by the above-mentioned structural formula.

The electron injecting layer of the intermediate unit is preferable to be formed using, for example, an alkali metal such as Li and Cs, an alkali metal oxide such as Li₂O, an alkaline earth metal, or an alkaline earth metal oxide.

The electron transporting layer of the intermediate unit may be formed using a material used generally as the material for the electron transporting layer in the organic EL element. For example, a metal chelate complex such as a tris(8-quinolinate)aluminum derivative, or an o-, m-, or p-phenanthroline derivative, or a silole derivative, or an oxadiazole derivative, or a triazole derivative can be exemplified.

Each of the light emitting units in the invention may comprise a single light emitting layer or a plurality of light emitting layers which are layered directly. For example, each light emitting unit may be a white-emitting unit formed by layering a blue emitting layer and an orange emitting layer.

The light emitting layer composing the light emitting units of the invention is preferable to comprise a host material and a dopant material. If necessary, it may contain a second dopant material having a carrier transporting property. The dopant material may be a singlet light emitting material or a triplet light emitting material (a phosphorescent emitting material).

A bottom emission-type organic electroluminescent display device in accordance with the invention comprises organic electroluminescent elements each having an element structure sandwiched between an anode and a cathode, and an active matrix driving substrate having each active element for supplying a display signal for each display pixel to the organic electroluminescent elements, in which each organic electroluminescent element is provided on the active matrix driving substrate and, between the cathode and the anode, an electrode provided on the substrate side is a transparent electrode, and is characterized in that each of the organic electroluminescent element is provided with a cathode, an node, a plurality of light emitting units arranged between the cathode and the anode via intermediate units, a cavity adjustment layer formed between the light emitting unit nearest to the anode and the anode, and an electron extracting layer formed adjacently to the cavity adjustment layer in the light emitting unit side and the optical distance from the light emitting position of each light emitting unit to the anode is adjusted by adjusting the film thickness of the cavity adjustment layer.

A top emission-type organic electroluminescent display device in accordance with the invention comprises organic electroluminescent elements each having an element structure sandwiched between an anode and a cathode, an active matrix driving substrate having each active element for supplying a display signal for each display pixel to the organic electroluminescent elements, and a transparent sealing substrate provided opposite to the active matrix driving substrate, in which each organic electroluminescent element is arranged between the active matrix driving substrate and the sealing substrate and, between the cathode and the anode, the electrode provided on a sealing substrate side is a transparent electrode, and is characterized in that each organic electroluminescent element is provided with a cathode, an anode, a plurality of light emitting units arranged between a cathode and an anode via intermediate units, a cavity adjustment layer formed between the light emitting unit nearest to the anode and the anode, and an electron extracting layer formed adjacently to the cavity adjustment layer in the light emitting unit side and the optical distance from the light emitting position of each light emitting unit to the anode is adjusted by adjusting the film thickness of the cavity adjustment layer.

In the case where an organic electroluminescent element is a white emitting element, it is preferable to install a color filter. In the case of the bottom emission-type organic EL display device, it is preferable that the color filter is installed between the active matrix driving substrate and the organic EL elements. In the case of the top emission-type organic EL display device, it is preferable that the color filter is installed between the sealing substrate and the organic EL elements.

In the case of a top emission type display device, the light emitted from an organic EL element is emitted out of the sealing substrate on the opposite to the side where the active matrix is formed. Generally, the active matrix circuit is formed by layering a large number of layers and in the case of the bottom emission type, due to the existence of the active matrix driving substrate, the emitted light is attenuated, however in the case of the top mission type, light can be emitted without being affected by the active matrix circuit.

The light emitting device of the invention is characterized in that the above-mentioned organic electroluminescent elements of the invention are employed.

### SECOND ASPECT OF THE INVENTION

An organic EL element of the invention comprises a cathode, an anode, an intermediate unit arranged between the cathode and the anode, a first light emitting unit arranged between the cathode and the intermediate unit, a second light emitting unit arranged between the anode and the intermediate unit, and a cavity adjustment unit arranged between the intermediate unit and the second light emitting unit, while adjoining the intermediate unit and is characterized in

that the intermediate unit comprises a first electron extracting layer for extracting an electron from the cavity adjustment unit and an electron injecting layer adjoining the anode side of the first electron extracting layer:

that the cavity adjustment unit is formed adjoining the cathode side of the first electron extracting layer and comprises a first cavity adjustment layer from which an electron is extracted by the first electron extracting layer and a second electron extracting layer for extracting an electron from an electron supply layer adjoining the cathode side:

that the absolute value of an energy level |LUMO (B)| of the lowest unoccupied molecular orbital (LUMO) of the first electron extracting layer and the absolute value of an energy level |HOMO (A)| of the highest occupied molecular orbital (HOMO) of the first cavity adjustment layer are in the relationship of |HOMO (A)|−|LUMO (B)|≦1.5 eV and the absolute value of an energy level |LUMO (C)| of the lowest unoccupied molecular orbital (LUMO) or the absolute value of the work function |WF (C)| of the electron injecting layer is lower than |LUMO (B)|: and

that the absolute value of an energy level |LUMO (D)| of the lowest unoccupied molecular orbital (LUMO) of the second electron extracting layer and the absolute value of an energy level |HOMO (E)| of the highest occupied molecular orbital (HOMO) of the electron supply layer are in the relationship of |HOMO (E)|−|LUMO (D)|≦1.5 eV and the absolute value of an energy level |LUMO (A)| of the lowest unoccupied molecular orbital (LUMO) of the first cavity adjustment layer and |LUMO (D)| are in the relationship of |LUMO (A)|≦|LUMO (D)|.

In this invention, the intermediate unit is formed between the first light emitting unit and the second light emitting unit and the cavity adjustment unit is formed between the intermediate unit and the first light emitting unit, while adjoining the intermediate unit. Accordingly, the cavity can be adjusted by adjusting the film thickness of the cavity adjustment unit. The light emitted in the second light emitting unit is transmitted through the intermediate unit, the cavity adjustment unit and the first light emitting unit and reflected by the cathode generally formed to be a metal thin film and again transmitted through the first light emitting unit, the cavity adjustment unit, the intermediate unit, the first light emitting unit, and the anode and emitted outside. Accordingly, the cavity of the light emitted in the second light emitting unit can be efficiently adjusted by adjusting the film thickness of the cavity adjustment unit.

The intermediate unit comprises a first electron extracting layer for extracting an electron from the cavity adjustment unit and an electron injecting layer adjoining the anode side of the first electron extracting layer.

The cavity adjustment unit comprises a first cavity adjustment layer formed adjoining the cathode side of the first electron extracting layer and from which an electrode is extracted by the first electron extracting layer and a second electron extracting layer for extracting an electron from the electron supply layer positioned in the cathode side.

In the intermediate unit, the |LUMO (B)| of the first electron extracting layer and the |HOMO (A)| of the first cavity adjustment layer are in the relationship of |LUMO (A)|−|LUMO (B)|≦1.5 eV . . . (1).

Accordingly, the first electron extracting layer can easily extract an electron from the neighboring first cavity adjustment layer.

Also, the |LUMO (C)| or the |WF (C)| of the electron injecting layer adjoining the anode side of the first electron extracting layer and the |LUMO (B)| of the first electron extracting layer are in the relationship of LUMO (C)| or |WF (C)|≦|LUMO (B)| . . . (2). Accordingly, an electron extracted by the first electron extracting layer is supplied to the electron injecting layer and then to the second light emitting unit from the electron injecting layer.

The |LUMO (D)| of the second electron extracting layer and the |HOMO (E)| of the electron supply layer adjoining the cathode side of the second electron extracting layer in the cavity adjustment unit are in the relationship of |H HOMO (E)|−|LUMO (B)|≦1.5 eV . . . (3).

Accordingly, the second electron extracting layer can easily extract an electron from the electron supply layer. Also, the |LUMO (A)| of the first cavity adjustment layer and the |LUMO (D)| of the second electron extracting layer are in the relationship of |LUMO (A)|≦|LUMO (D)| . . . (4). Accordingly, an electron extracted by the second electron extracting layer is blocked by the first cavity adjustment layer and the electron is accumulated in the second electron extracting layer. Therefore, it is supposed to be possible that a high electric field is locally applied and the energy band is changed due to the high electric field and even if the film thickness of the first cavity adjustment layer is made thick, the driving voltage is prevented from becoming high.

In the intermediate unit of the invention, the first electron extracting layer extracts an electron from the first cavity adjustment layer of the cavity adjustment unit and supplies the extracted electron to the second light emitting unit in the anode side via the electron extracting layer. In the second light emitting unit, a hole supplied from the anode is bonded with the electron to emit light. On the other hand, a hole is generated in the first cavity adjustment layer from which the electron is extracted.

In the cavity adjustment unit, the second electron extracting layer extracts an electron from the adjacent electron supply layer and the extracted electron is accumulated in the second electron extracting layer as described above and accordingly, a high electric field is locally generated. The electron accumulated in the second electron extracting layer is bonded with a hole generated in the first cavity adjustment layer. In the electron supply layer from which the electron is extracted, a hole is generated and the hole is supplied to the first light emitting unit in the cathode side and bonded with the electron supplied from the cathode and thus the first light emitting unit emits light.

As described above, in the invention, since an electron is supplied to the second light emitting units in the anode side from the intermediate unit and the cavity adjustment unit and a hole is supplied to the first light emitting unit in the cathode side, light emission is carried out efficiently in the respective light emitting units. Also, as described above, an electron is accumulated in the second electron extracting layer, so that a high electric field is locally applied. Therefore, even if the film thickness of the first cavity adjustment layer in the cavity adjustment unit is made thick, increase of the driving voltage is suppressed and accordingly, a high light emitting efficiency can be obtained.

Further, in the invention, as described above, an electron is blocked by the first cavity adjustment layer of the cavity adjustment unit. Accordingly, since supply of an excess quantity of electrons to the anode side can be prevented, the element life can be prolonged and the reliability of the element can be heightened.

In the invention, the electron supply layer is preferable to be formed using a hole transporting material. If the light emitting layer to be formed in the first light emitting unit contains the hole transporting material as a host material, the light emitting layer may be used as the electron supply layer. Accordingly, the electron supply layer may be formed in the first light emitting unit in the invention.

Also, in the invention, the electron supply layer may be a second cavity adjustment layer to be formed in the cavity adjustment unit. In this case, in addition to the first cavity adjustment layer, the second cavity adjustment layer can be made to have a thick film thickness and may be used for adjusting the cavity.

The first and the second cavity adjustment layers in the invention are preferable to be formed using a hole transporting material. Such a hole transporting material includes tertiary arylamine type materials.

Also, in the invention, the cavity adjustment unit may be composed by combining the first cavity adjustment layer and the second electron extracting layer and may comprise a plurality of repeating units of these layers. That is, the cavity adjustment unit may have a layered structure of first cavity adjustment layer/second electron extracting layer/first cavity adjustment layer/second electron extracting layer or a layered structure of first cavity adjustment layer/second electron extracting layer/first cavity adjustment layer/second electron extracting layer/first cavity adjustment layer/second electron extracting layer. The preferable film thickness of the cavity adjustment layer is generally in a range from 10 to 700 nm. If the film thickness of the cavity adjustment layer is too thick, it results in occurrence of problems that the driving voltage becomes to high and that the light emitting efficiency is lowered. Therefore, in the case where the film thickness of the cavity adjustment layer is to be thicker than the above-mentioned range, it is preferable to properly insert a second electron extracting layer and form a plurality of repeating units of the first cavity adjustment layer and the second electron extracting layer.

Also, in the invention, an electron transporting layer may be formed between the electron injecting layer of the intermediate unit and the second light emitting unit. The absolute value of an energy level |LUMO (F)| of the lowest unoccupied molecular orbital (LUMO) of the electron transporting layer is set to be lower than the |LUMO (C)| or the |WF (C)|.

In the invention, the |HOMO (A)| of the first cavity adjustment layer and the |HOMO (D)| of the second electron extracting layer are preferable to be in the relationship of |HOMO (A)|≦|HOMO (D)| . . . (5)

If the above-mentioned formula (5) is satisfied, it is supposed that a hole is accumulated in the interface of the first cavity adjustment layer and the second electron extracting layer and accordingly, a high electric field can be locally applied and the driving voltage can be lowered.

In the invention, as a material for forming the first and/or the second electron extracting layers, a pyrazine derivative defined by the following structural formula can be exemplified: 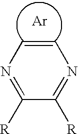
wherein Ar denotes an aryl group; R denotes hydrogen; an alkyl, an alkyloxy, or an dialkylamine group having 1 to 10 carbon atoms; or F, Cl, Br, I, or CN.

Also, in the invention, it is more preferable to use a hexaazatriphenylene derivative defined by the following structural formula for the material for forming the first and/or the second electron extracting layers: 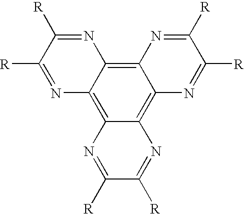
wherein R denotes hydrogen; an alkyl, an alkyloxy, or an dialkylamine group having 1 to 10 carbon atoms; or F, Cl, Br, I, or CN.

In the invention, the first and/or the second electron extracting layers may be doped with an electron extraction-promoting material for promoting the electron extraction. The absolute value of an energy level |LUMO (G)| of the lowest unoccupied molecular orbital (LUMO) of the electron extraction-promoting material is preferable to satisfy the following relationship: |HOMO (A)| or |HOMO (E)|≧|LUMO (G)|≧|LUMO (B)| or |LUMO (D)| . . . (6).

The difference between |HOMO (A)| and |LUMO (G)| or the different between |HOMO (E)| and |LUMO (G)| is preferably 1.5 eV or lower. Even if the difference between |HOMO (A)| and |LUMO (B)| or the different between |HOMO (E)| and |LUMO (D)| becomes higher than 1.5 eV, for example, 2.0 eV, the electron extraction by the electron extracting layer can be easily carried out by controlling the difference as described above.

The first light emitting unit and the second light emitting unit in the invention may independently comprise a single light emitting layer or may have a layered structure formed by layering a plurality of the light emitting layers. For example, they may independently be a white emitting unit formed by layering an orange emitting layer or a blue emitting layer.

An organic electroluminescent display device in accordance with the invention is a bottom emission type organic electroluminescent display device comprising organic electroluminescent elements each having an element structure sandwiched between an anode and a cathode, and an active matrix driving substrate having each active element for supplying a display signal for each display pixel to the organic electroluminescent elements, in which each organic electroluminescent element is provided on the active matrix driving substrate and, between the cathode and the anode, an electrode provided on the substrate side is a transparent electrode, and is characterized in that each organic electroluminescent element comprises the cathode, the anode, an intermediate unit arranged between the cathode and the anode, a first light emitting unit arranged between the cathode and the intermediate unit, a second light emitting unit arranged between the anode and the intermediate unit, and a cavity adjustment unit arranged between the intermediate unit and the second light emitting unit, while adjoining the intermediate unit: that the intermediate unit comprises a first electron extracting layer for extracting an electron from the cavity adjustment unit and an electron injecting layer adjoining the anode side of the first electron extracting layer: that the cavity adjustment unit is formed adjoining the cathode side of the first electron extracting layer and comprises a first cavity adjustment layer from which an electron is extracted by the first electron extracting layer and a second electron extracting layer for extracting an electron from the electron supply layer adjoining the cathode side: and that the absolute value of an energy level |LUMO (B)| of the lowest occupied molecular orbital (LUMO) of the first electron extracting layer and the absolute value of an energy level |HOMO (A)| of the highest occupied molecular orbital (HOMO) of the first cavity adjustment layer are in the relationship of |HOMO (A)|−|LUMO (B)|≦1.5 eV; the absolute value of an energy level |LUMO (C)| of the lowest unoccupied molecular orbital (LUMO) or the absolute value of the work function |WF (C)| of the electron injecting layer is lower than |LUMO (B)|; the absolute value of an energy level |LUMO (D)| of the lowest unoccupied molecular orbital (LUMO) of the second electron extracting layer and the absolute value of an energy level |HOMO (E)| of the highest occupied molecular orbital (HOMO) of the electron supply layer are in the relationship of |HOMO (E) |−|LUMO (D)|≦1.5 eV; and the absolute value of an energy level |LUMO (A)| of the lowest unoccupied molecular orbital (LUMO) of the first cavity adjustment layer and the |LUMO (D)| are in the relationship of |LUMO (A)|≦|LUMO (D)|.

In the above-mentioned organic electroluminescent display device of the invention, if each organic EL element is a white emitting element, a color filter may be arranged between the organic EL element and the substrate to make the display device as a color display device.

An organic electroluminescent display device in accordance with another aspect of the invention is a top emission type organic electroluminescent display device comprising organic electroluminescent elements each having an element structure sandwiched between an anode and a cathode, an active matrix driving substrate having each active element for supplying a display signal for each display pixel to the organic electroluminescent elements, and a transparent sealing substrate provided opposite to the active matrix driving substrate, in which each organic electroluminescent element is arranged between the active matrix driving substrate and the sealing substrate and, between the cathode and the anode, the electrode provided on a sealing substrate side is a transparent electrode, and is characterized in that each organic electroluminescent element comprises the cathode, the anode, an intermediate unit arranged between the cathode and the anode, a first light emitting unit arranged between the cathode and the intermediate unit, a second light emitting unit arranged between the anode and the intermediate unit, and a cavity adjustment unit arranged between the intermediate unit and the second light emitting unit, while adjoining the intermediate unit: that the intermediate unit comprises a first electron extracting layer for extracting an electron from the cavity adjustment unit and an electron injecting layer adjoining the anode side of the first electron extracting layer: that the cavity adjustment unit is formed adjoining the cathode side of the first electron extracting layer and comprises a first cavity adjustment layer from which an electron is extracted by the first electron extracting layer and a second electron extracting layer for extracting an electron from the electron supply layer adjoining the cathode side: and that the absolute value of an energy level |LUMO (B)| of the lowest unoccupied molecular orbital (LUMO) of the first electron extracting layer and the absolute value of an energy level |HOMO (A)| of the highest occupied molecular orbital (HOMO) of the first cavity adjustment layer are in the relationship of |HOMO (A)|−|LUMO (B)|≦1.5 eV; the absolute value of an energy level |LUMO (C)| of the lowest unoccupied molecular orbital (LUMO) or the absolute value of the work function |WF (C)| of the electron injecting layer is lower than |LUMO (B)|; the absolute value of an energy level |LUMO (D)| of the lowest unoccupied molecular orbital (LUMO) of the second electron extracting layer and the absolute value of an energy level |HOMO (E)| of the highest occupied molecular orbital (HOMO) of the electron supply layer are in the relationship of |HOMO (E)|−|LUMO (D)|≦1.5 eV; and the absolute value of an energy level |LUMO (A)| of the lowest unoccupied molecular orbital (LUMO) of the first cavity adjustment layer and the |LUMO (D)| are in the relationship of |LUMO (A)|≦|LUMO (D)|.

In the above-mentioned organic electroluminescent display device, if each organic EL element is a white emitting element, a color filter may be arranged between the organic EL element and the sealing substrate to make the display device as a color display device.

Since the organic EL display device of the invention comprises the above-mentioned organic EL elements of the invention, the cavity can be adjusted for every light emitting color and the driving voltage can be lowered to save the power consumption. Further, the organic EL display device is provided with a high reliability.

### THIRD ASPECT OF THE INVENTION

An organic electroluminescent element of the invention comprises a reflective electrode, a light output side electrode, a first light emitting layer and a second light emitting layer arranged between the reflective electrode and the light output side electrode and is characterized in that the optical distance between the light emitting position of the first light emitting layer and the reflection face of the reflective electrode is (n/x)λ and the optical distance between the light emitting position of the second light emitting layer and the reflection face of the reflective electrode is [(n+m)/2x]]λ, wherein λ denotes the mean wavelength of a desired light emission; n is an odd number; m is an even number; and x is a natural number.

The light emission intensity from the first light emitting layer in the front direction of each organic EL element is made to be the maximum and the light emission intensity from the second light emitting layer in the direction at a visible angle 60° of each organic EL element is made to be the maximum by adjusting the optical distance between the light emitting position of the first light emitting layer and the reflection face of the reflective electrode to be (n/x)λ and the optical distance between the light emitting position of the second light emitting layer and the reflection face of the reflective electrode to be [(n+m)/2x)]λ according to the invention. That is, since the light emission intensity from the first light emitting layer in the front direction of each organic EL element is made to be the maximum and the light emission intensity from the second light emitting layer in the direction at a visible angle 60° of each organic EL element is made to be the maximum, the visible angle-dependency can be lowered.

FIG. 8 shows a schematic view for illustrating the above-mentioned functional effect. In FIG. 8, the light emitting position of the first light emitting layer is defined as a light source 101 and the light emitting position of the second light emitting layer as a light source 102. The optical distance between the light source 101 and the reflection surface 103 of the reflective electrode is set to be (n/x)λ and the optical distance between the light source 102 and the reflection surface 103 of the reflective electrode is set to be [(n+m)/2x)]λ.

As shown in FIG. 8, in the direction at a visible angle of 60°, the optical distance between the light source 101 and the reflection surface 103 of the reflective electrode is set to be (2n/x), and the optical distance between the light source 102 and the reflection surface 103 of the reflective electrode is set to be [(n+m)/x)]λ. Accordingly, in the front direction, the optical distance between the light source 101 and the reflection surface 103 of the reflective electrode is as long as an odd number times of the mean wavelength λ of the desired light emission and thus the optical distance satisfies the resonance condition to give the maximum light emission intensity.

On the other hand, in the direction at a visible angle of 60°, the optical distance between the light source 102 and the reflection surface 103 of the reflective electrode is as long as an odd number times of the mean wavelength λ of the desired light emission and thus the light emission intensity from the light source 102 becomes the maximum.

Accordingly, it is made possible that the light emission intensity in the front direction from the first light emitting layer becomes the maximum and the light emission intensity in the direction at a visible angle of 60° from the second light emitting layer becomes the maximum, so that the visible angle-dependency can be lowered.

Additionally, although the light source 101 is set nearer to the reflection surface 103 of the reflective electrode than the light source 102, the invention is not particularly limited to that, but the light source 102, that is, the light emitting position of the second light emitting layer may be positioned nearer to the reflection surface 103 of the reflective electrode than the light source 101, that is, the light emitting position of the first light emitting layer.

In the invention, the first light emitting layer and the second light emitting layer are preferable to be layered via an intermediate unit.

In the case where the first light emitting layer is arranged between the reflective electrode and the intermediate unit and the second light emitting layer is arranged between the light output side electrode and the intermediate unit, it is preferable that the first cavity adjustment layer is formed between the reflective electrode and the first light emitting layer and that the second cavity adjustment layer is formed between the intermediate unit and the second light emitting layer. The optical distance between the light emitting position of the first light emitting layer and the reflection surface of the reflective electrode and the optical distance between the light emitting position of the second light emitting layer and the reflection surface of the reflective electrode can be easily adjusted by adjusting the film thickness of the first cavity adjustment layer and the second cavity adjustment layer.

The first cavity adjustment layer and the second cavity adjustment layer are preferable to be formed using a hole transporting material.

Also, in the invention, the intermediate unit is preferable to comprise an electron extracting layer, an electron injecting layer, and an electron transporting layer. In the invention, one of the reflective electrode and the light output side electrode is the anode and the other is the cathode and in the intermediate unit, the electron extracting layer is installed in the cathode side and the electron injecting layer is formed while adjoining the anode side of the electron extracting layer. The electron transporting layer is installed adjoining the anode side of the electron injecting layer.

In the intermediate unit composed as described above-mentioned, the electron extracting layer extracts an electron from the adjacent layer adjoining the anode side and supplies the extracted electron to the anode side via the electron injecting layer and the electron transporting layer and a hole generated in the adjacent layer by the electron extraction is supplied to the cathode side. Therefore, light emission is carried out at a high efficiency in the light emitting layers in both sides sandwiching the intermediate unit.

It is preferable that the absolute value of an energy level |LUMO (A)| of the lowest unoccupied molecular orbital (LUMO) of the electron extracting layer and the absolute value of an energy level |HOMO (B)| of the highest occupied molecular orbital (HOMO) of the adjacent layer are in the relationship of |HOMO (B)|−|LUMO (A)|≦1.5 eV and that the absolute value of an energy level |LUMO (C)| of the lowest unoccupied molecular orbital (LUMO) or the absolute value of the work function |WF (C)| of the electron injecting layer is lower than |LUMO (A)|.

The intermediate unit supplies a hole generated by electron extraction from the adjacent layer by the electron extracting layer formed in the intermediate unit to the light emitting unit positioned in the cathode side and at the same time supplies the extracted electron to the light emitting unit positioned in the anode side via the electron injecting layer.

Hereinafter, in the description of the intermediate unit, the light emitting layer positioned in the cathode side is called as the first light emitting layer and the light emitting layer positioned in the anode side is called as the second light emitting layer.

As described above, the absolute value of an energy level |HOMO (B)| of HOMO of the adjacent layer and the absolute value of an energy level |LUMO (A)| of LUMO of the electron extracting layer are in the relationship of |HOMO (B)|−|LUMO (A)|≦1.5 eV and it is preferable that the energy level of LUMO of the electron extracting layer is a near value to the energy level of HOMO of the adjacent layer, in the intermediate unit. Accordingly, the electron extracting layer can extract an electron from the adjacent layer. Due to the electron extraction from the adjacent layer, a hole is generated in the adjacent layer. In the case where the adjacent layer is formed in the first light emitting layer, the hole is generated in the first light emitting layer. Also, in the case where the adjacent layer is formed between the electron extracting layer and the first light emitting layer, that is, the adjacent layer is formed in the intermediate unit, the hole generated in the adjacent layer is supplied to the first light emitting layer. The hole supplied to the first light emitting layer is recombined with an electron from the cathode and accordingly the first light emitting layer emits light.

On the other hand, the electron extracted by the electron extracting layer moves to the electron injecting layer and is supplied to the second light emitting layer via the electron injecting layer and the electron transporting layer and recombined with the hole supplied from the anode and accordingly the second light emitting layers emits light.

In the intermediate unit, to extract an electron from the adjacent layer by the electron extracting layer, it is preferable that the energy level of LUMO of the electron extracting layer is nearer to the energy level of HOMO of the adjacent layer than to the energy level of LUMO of the adjacent layer. That is, it is preferable that the absolute value of an energy level |LUMO (B)| of LUMO of the adjacent layer satisfies the following relationship: |HOMO (B)|−|LUMO (A)|≦|LUMO (A)|−|LUMO (B)|.

Also, since the absolute value of the energy level of LUMO of the material to be used for the electron extracting layer is generally lower than the absolute value of the energy level of HOMO of the adjacent layer, in such a case, the absolute values of the respective energy levels are in relationship defined by the following formula:
0 eV<|HOMO (B)|−|LUMO (A)|≦1.5 eV.

The absolute value of an energy level |LUMO (C)| of LUMO or the absolute value of the work function |WF (C)| of the electron injecting layer is preferable to be lower than the absolute value of an energy level |LUMO (A)| of LUMO of the electron extracting layer and accordingly the electron extracted from the electron extracting layer moves to the electron injecting layer and is supplied to the second light emitting layer via the electron injecting layer and the electron transporting layer.

The electron transporting layer is formed between the electron injecting layer and the second light emitting layer in the intermediate unit. The absolute value of an energy level |LUMO (D)| of LUMO of the electron transporting layer is preferable to be lower than the absolute value of an energy level |LUMO (C)| of LUMO or the absolute value of the work function |WF (C)| of the electron injecting layer. The electron moved to the electron injecting layer is supplied to the second light emitting layer via the electron transporting layer.

The electron extracting layer in the invention may be formed, for example, using a pyrazine derivative defined by the following structural formula: 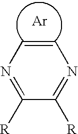
wherein Ar denotes an aryl group; R denotes hydrogen; an alkyl, an alkyloxy, or an dialkylamine group having 1 to 10 carbon atoms; or F, Cl, Br, I, or CN.

In the invention, more preferably, the electron extracting layer may be formed using a hexaazatriphenylene derivative defined by the following structural formula: 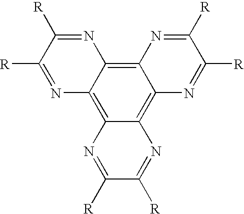
wherein R denotes hydrogen; an alkyl, an alkyloxy, or an dialkylamine group having 1 to 10 carbon atoms; or F, Cl, Br, I, or CN.

Also, the electron injecting layer of the intermediate unit is preferable to be formed using, for example, an alkali metal such as Li and Cs, an alkali metal oxide such as Li₂O, an alkaline earth metal, or an alkaline earth metal oxide.

Further, the electron transporting layer of the intermediate unit may be formed using a material used generally as the material for the electron transporting layer in the organic EL element. For example, a metal chelate complex such as a tris(8-quinolinate)aluminum derivative, or an o-, m-, or p-phenanthroline derivative, or a silole derivative, or an oxadiazole derivative, or a triazole derivative can be exemplified.

In the invention, the first light emitting layer and the second light emitting layer are layered in the thickness direction of the element and they are respectively light emitting layers emitting the same color. They may be monochromic light emitting layers for emitting red (R), green (G), or blue (B) or may be white emitting layers. In the case of the white emitting layers, each layer may have a structure comprising an orange emitting layer and a blue emitting layer layered on each other.

Even if the optical distances defined in the invention are different from (n/x)λ and [(n+m)/2x]]λ to an extent that the differences are within a slight range, the same effects of the invention can be achieved. Accordingly, the optical distances defined in the invention are allowed to have an error margin of ±10% from the above described ranges.

### EFFECTS OF THE FIRST TO THE THIRD ASPECTS OF THE INVENTION

The organic EL element of the first aspect of the invention is an organic EL element comprising a plurality of layered light emitting units and is capable of easily adjusting the cavity without changing the film thickness in the respective light emitting units. Accordingly, the organic EL element can be an organic EL element having a desired light emitting color and high light extraction quantity from the organic EL.

According to the second aspect of the invention, an organic EL element in which the cavity can be adjusted and which has a high light emitting efficiency, can lower the driving voltage, and can heighten the reliability and an organic EL display device using the organic EL element can be provided.

According to the third aspect of the invention, the visible angle dependency of an organic EL element can be lowered by forming at least a first light emitting layer and a second light emitting layer as a light emitting layer and adjusting the optical distance optical distance between the light emitting position of the first light emitting layer and the reflection face of a reflective electrode to be (n/x)λ and the optical distance between the light emitting position of the second light emitting layer and the reflection face of the reflective electrode to be [(n+m)/2x)]λ.

### BRIEF DESCRIPTION OF DRAWINGS

FIG. 1 is a schematic cross-sectional view showing an organic EL element of one embodiment according to the first aspect of the invention.

FIG. 2 is a graph showing the relationship between the driving time and the light emission intensity of an example according to the first aspect of the invention and a reference example.

FIG. 3 is a graph showing the relationship between the film thickness of the cavity adjustment layer and the driving voltage.

FIG. 4 is a diagram showing an organic EL display device of one embodiment according to the first aspect of the invention. FIG. 5 is a schematic view showing the energy levels of LUMO and HOMO of the respective layers composing the intermediate unit and the cavity adjustment unit in one embodiment according to the second aspect of the invention.

FIG. 6 is a cross-sectional view showing a bottom-emission type organic EL display device of one embodiment according to the second aspect of the invention.

FIG. 7 is a cross-sectional view showing a top-emission type organic EL display device of one embodiment according to the second aspect of the invention.

FIG. 8 is a schematic view illustrating the functional effect of the third aspect of the invention.

FIG. 9 is a schematic cross-sectional view showing an organic EL element of one embodiment according to the third aspect of the invention.

FIG. 10 is a graph showing a light emission spectrum in the front direction and a light emission spectrum in the direction at a visible angle of 60° of an organic EL element of one embodiment according to the third aspect of the invention.

FIG. 11 is a schematic cross-sectional view showing an organic EL element of Comparative Example 7.

FIG. 12 is a graph showing a light emission spectrum in the front direction and a light emission spectrum in the direction at a visible angle of 600 of the organic EL element of Comparative Example 7.

### DESCRIPTION OF THE PREFERRED EXAMPLES

### FIRST ASPECT OF THE INVENTION

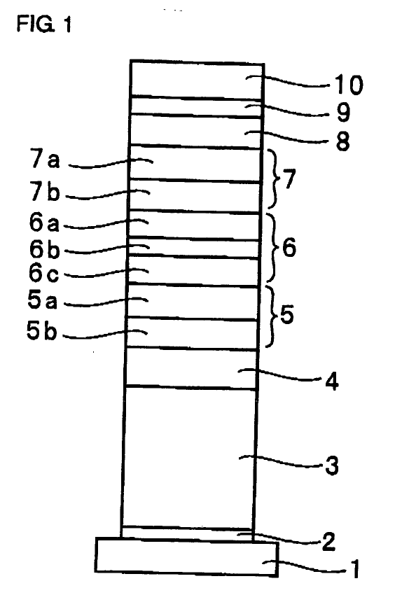

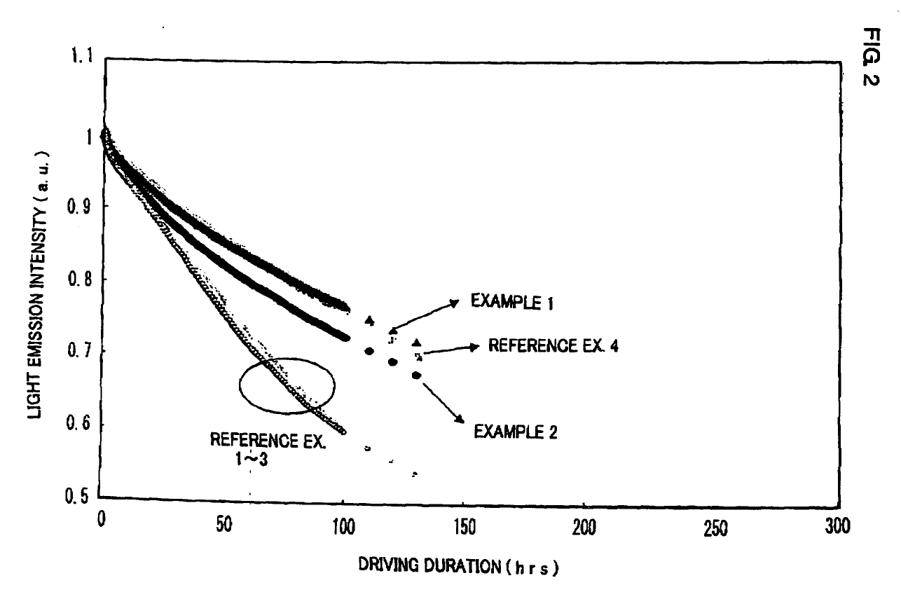

FIG. 1 is a schematic cross-sectional view showing an organic EL element according to the invention.

An anode 1 which is formed of an ITO (an indium tin oxide) film is formed on a glass substrate and a hole injecting layer 2 of a fluorocarbon (CFₓ) layer is formed on the anode 1. On the hole injecting layer 2, a cavity adjustment layer 3 containing a hole transporting material such as NPB is formed. On the cavity adjustment layer 3, an electron extracting layer 4 is formed.

On the electron extracting layer 4, a first light emitting unit 5 and a second light emitting unit 7 are formed and an intermediate unit 6 is formed between the first light emitting unit 5 and the second light emitting unit 7. The first light emitting unit 5 is composed by layering a blue emitting layer 5a on an orange emitting layer 5b and similarly, the second light emitting unit 7 is composed by layering a blue emitting layer 7a on an orange emitting layer 7b. Accordingly, the first light emitting unit 5 and the second light emitting unit 7 are both white emitting units.

The intermediate unit 6 is composed of an electron transporting layer 6c formed on the blue emitting layer 5a, an electron injecting layer 6b formed on the electron transporting layer 6c, and an electron extracting layer 6a formed on the electron injecting layer 6b.

An electron transporting layer 8 is formed on the second light emitting unit 7 and an electron injecting layer 9 is formed on the electron transporting layer 8. A cathode 10 is formed on the electron injecting layer 9.

In Example shown in FIG. 1, the light from the first light emitting unit 5 is radiated toward the anode 1 and also toward the cathode 10. The light emitted to the cathode 10 is reflected by the surface of the cathode 10 since the cathode 10 is made to be a reflective electrode and radiated toward the anode 1 side.

Further, the light from the second light emitting unit 7 is also radiated to toward the anode 1 side and radiated toward the cathode 10 side and the light reflected by the surface of the cathode 10 is radiated toward the anode 1 side.

Accordingly, to increase the quantity of the light radiated form the organic EL element by adjusting the interference of these light rays, it is required to adjust the cavity. In the invention, since the cavity adjustment layer 3 is formed, the optical distances from the respective light emitting positions of the first light emitting unit 5 and the second light emitting unit 7 to the anode 1 can be adjusted by adjusting the film thickness of the cavity adjustment layer 3 and thus the cavity adjustment can be easily carried out.

In this Example, the intermediate unit 6 is installed between the first light emitting unit 5 and the second light emitting unit 7. The electron extracting layer 6a of the intermediate unit 6 extracts an electron from the adjacent orange emitting layer 7b and supplies a hole generated thereby to the second light emitting unit 7 side and at the same time supplies the extracted electron to the first light emitting unit 5 via the electron injecting layer 6b and electron transporting layer 6c. The hole supplied to the second light emitting unit 7 is recombined with an electron supplied from the cathode 10, so that the second light emitting unit 7 can emit light. Also, the electron supplied to the first light emitting unit 5 is recombined with a hole supplied from the anode 1, so that the first light emitting unit 5 can emit light. Accordingly, formation of the intermediate unit 6 allows the first light emitting unit 5 and the second light emitting unit 7 to efficiently emit light.

The electron extracting layer 4 is formed adjacently to the cavity adjustment layer 3 in the first light emitting unit 5 side. Formation of the electron extracting layer 4 makes it possible to improve the life property of the element as described below.

In the invention, a second electron extracting layer may be also formed in the cathode side. That is, a second electron extracting layer may be formed adjacently to the cavity adjustment layer 3 in the hole injecting layer 2 side. Formation of the second electron extracting layer can improve the heat resistance and the light fastness of the element.

[Fabrication of White Emitting Element]

### EXAMPLES 1 TO 7 AND REFERENCE EXAMPLES 1 TO 5

Organic EL elements of Examples 1 to 7 and Reference Examples 1 to 5 having the structure described with reference to FIG. 1 were fabricated. The compositions of the respective layers are as shown in Table 1.

TABLE 1

| | | Second | | First | | | | | |
|---|---|---|---|---|---|---|---|---|---|
| | Hole | Electron | Cavity | Electron | | | | | |
| | Injecting | Extracting | Adjustment | Extracting | First Light Emitting | | | | |
| Anode | Layer | Layer | Layer | Layer | Unit | | Intermediate Unit | | |
| ITO | CFx | As Shown | As Shown | As Shown | NPB + | TBADN + | BCP | Li₂O | HAT- |
| | | in Table 2 | in Table 2 | in Table 2 | 20% | 10% | (15) | (0.5) | CN6 |
| | | | | | TBADN + | NPB + | | | (20) |
| | | | | | 3% DBzR | 2% TBP | | | |
| | | | | | (60) | (50) | | | |

| | | | |
|---|---|---|---|
| | Electron | Electron | |
| | Transporting | Injecting | |
| Second Light Emitting Unit | Layer | Layer | Cathode |

| | | | | |
|---|---|---|---|---|
| NPB + | TBADN + | BCP | LiF | Al |
| 20% TBADN + | 10% NPB + | (15) | (1) | (200) |
| 3% DBzR | 2% TBP | | | |
| (60) | (50) | | | |

A fluorocarbon layer, which is a hole injecting layer, was formed by plasma polymerization of CRF₃ gas. The thickness of the fluorocarbon layer was adjusted to be 1 nm.

The cavity adjustment layer was formed using NPB, as shown in Table 2. NPB is N,N′-di(naphthacen-1-yl)-N,N′-diphenylbenzidine and has the following structure.

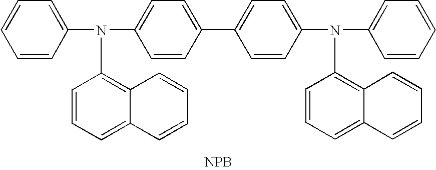

The first electron extracting layer and the second electron extracting layer were formed using HAT-CN6. HAT-CN6 is hexaazatirphenylene hexacarbonitrile and having the following structure.

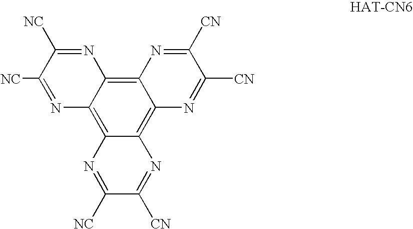

The cavity adjustment layer, the first electron extracting layer and the second electron extracting layer were formed in the film thickness described in Table 2. The unit is nm.

The first light emitting unit and the second light emitting unit were composed respectively by layering a blue emitting layer on an orange emitting layer as shown in Table 1.

The orange emitting layer is formed using 80% by weight of NPB, a hole transporting material, as a host material and 20% by weight of TBADN and DBzR, which is an orange emitting dopant, in an amount of 3% by weight to the total 100% by weight of NPB and TBADN. In this case, TBADN works as an energy transporting auxiliary dopant for transmitting the excitation energy from the host material to DBzR, the orange emitting dopant. Herein, the energy transporting auxiliary dopant is a material having a level of LUMO (the lowest unoccupied molecular orbital) and an energy gap between those of the host and the light emitting dopant and means a dopant having a function of efficiently transmitting the excitation energy from the host to the light emitting dopant.

TBADN is 2-tert-butyl-9,10-di(2-naphthyl)anthracene and has the following structure.

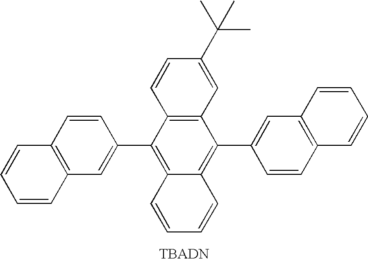

DBZR is 5,12-bis{4-(6-methylbenzothiazol-2-yl)phenyl}-6,11-diphenylnaphthacene and has the following structure.

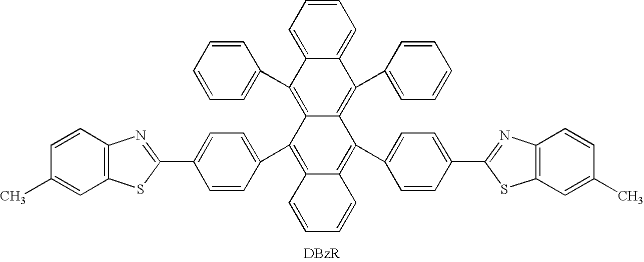

The blue emitting layer is formed using TBADN, an electron transporting material, as a host material, NPB as a carrier transporting auxiliary dopant, and TBP as a blue emitting dopant. The content of TBADN is 80% by weight, the content of NPB is 20% by weight, and the content of TBP is 2.5% by weight to the total 100% by weight of TBADN and NPB. In this case, the carrier transporting auxiliary dopant is a material with a high mobility of a carrier to be assisted as compared the host material and is a dopant having a function of increasing the light emitting efficiency by promoting the injection of one carrier and keeping the balance of the density of both carriers in a light emitting layer for increasing the recombining probability. In this case, NPB having higher hole transporting mobility than TBADN, which is an electron transporting material, has a function of assisting the movement of a hole in the blue emitting layer by being added to TBADN and accordingly increasing the light emitting efficiency. TBP is 2,5,8,11-tetra-tert-butylperylene and has the following structure.

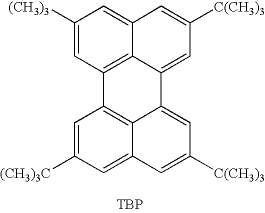

The electron transporting layer was formed using BCP. BCP is 2,9-dimethyl-4,7-diphenyl-1,10-phenanthroline and has the following structure.

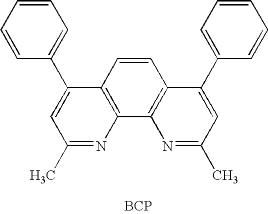

The intermediate unit was composed by, as shown in Table 1, forming the electron transporting layer using BCP, the electron injecting layer using Li₂O, and the electron extracting layer using HAT-CN6

The electron injecting layer was formed using LiF and the cathode was made of Al. The thickness of each layer was shown in Table 1 and Table 2. The unit is nm.

The driving voltage, chromaticity, and light emitting efficiency of the respective organic EL elements of Examples 1 to 7 and Reference Examples 1 to 6 are shown in Table 2.

TABLE 2

| | Second Electron | | First Electron | | | | | |
|---|---|---|---|---|---|---|---|---|
| | extracting Layer | Cavity Adjustment | Extracting Layer | | | | | |
| | HAT-CN6 | Layer NPB | HAT-CN6 | | | | | |
| | Film thickness | Film thickness | Film thickness | Voltage | Chromaticity | | Efficiency | |
| | (nm) | (nm) | (nm) | (V) | CE(x, y) | | (lm/W) | (cd/A) |
| Ref. Ex. 1 | 0 | 0 | 0 | 7.6 | 0.32 | 0.46 | 15.7 | 37.5 |
| Ref. Ex. 2 | 0 | 50 | 0 | 7.9 | 0.34 | 0.40 | 13.0 | 33.1 |
| Ref. Ex. 3 | 0 | 100 | 0 | 8.6 | 0.32 | 0.45 | 12.7 | 34.5 |
| Ref. Ex. 4 | 0 | 0 | 10 | 7.8 | 0.33 | 0.45 | 15.9 | 38.1 |
| Ex. 1 | 0 | 50 | 10 | 8.0 | 0.31 | 0.37 | 12.6 | 32.1 |
| Ex. 2 | 0 | 100 | 10 | 8.3 | 0.30 | 0.46 | 13.6 | 36.8 |
| Ex. 3 | 0 | 200 | 10 | 9.1 | 0.36 | 0.41 | 12.2 | 35.1 |
| Ex. 4 | 0 | 400 | 10 | 11.3 | 0.35 | 0.42 | 9.7 | 34.1 |
| Ex. 5 | 0 | 600 | 10 | 14.6 | 0.36 | 0.44 | 8.4 | 37.5 |
| Ref. Ex. 6 | 0 | 20 | 0 | 7.7 | 0.33 | 0.45 | 16.1 | 38.2 |
| Ex. 6 | 100 | 50 | 10 | 8.0 | 0.30 | 0.37 | 12.7 | 32.2 |
| Ex. 7 | 100 | 100 | 10 | 8.2 | 0.31 | 0.46 | 13.9 | 37.0 |

As shown in Table 2, it is understood that if the film thickness of the cavity adjustment layer is increased, the driving voltage is slightly increased and the light emitting efficiency tends to be slightly decreased, however the chromaticity is scarcely affected. Accordingly, it is found that as compared in a conventional case where the film thickness of each light emitting unit is changed, the cavity adjustment is made easy.

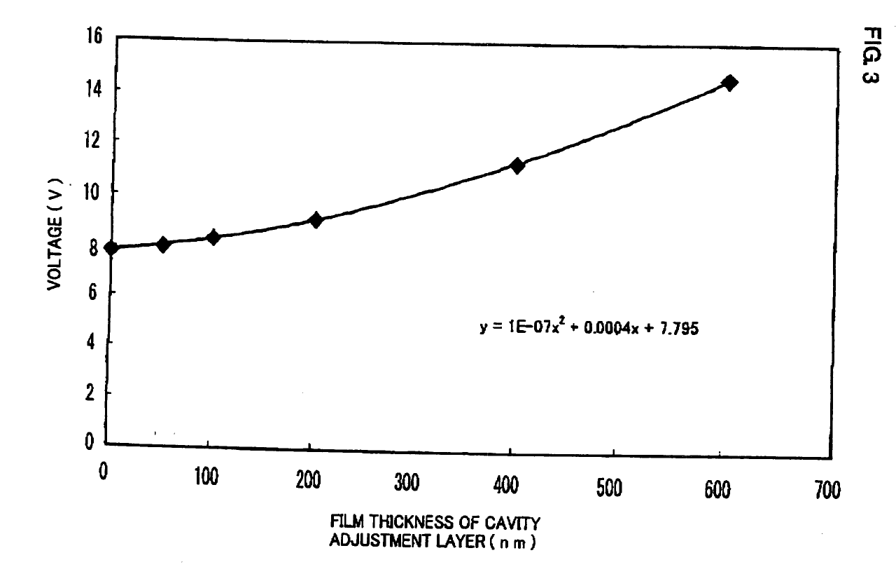

FIG. 2 shows a graph the relationship of the driving time and the light emission intensity of Examples 1 and 2 and Reference Examples 1 to 4. As shown in FIG. 2, it can be seen that Examples 1 and 2 and Reference Example 4 in which the first electron extracting layer was formed were provided with long driving duration and high light emission intensity and improved life property as compared with Reference Examples 1 to 3 in which the first electron extracting layer was not formed. Consequently, it is found that the life property can be improved by forming the first electron extracting layer.

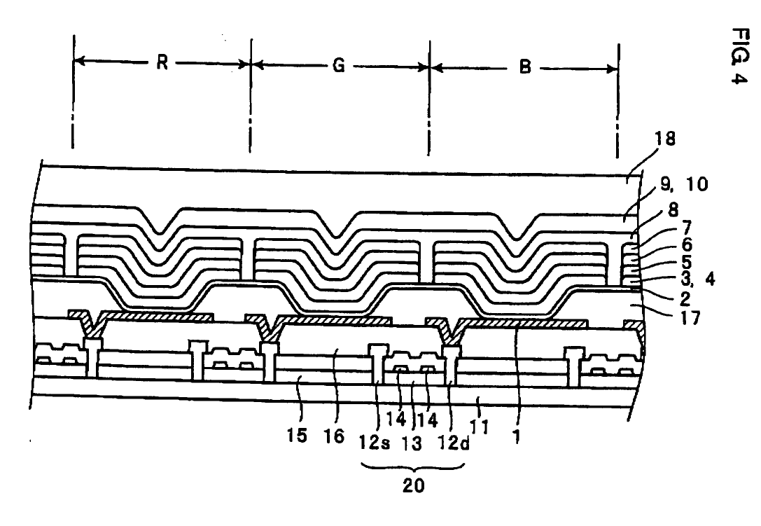

FIG. 3 is a graph showing the relationship between the film thickness of the cavity adjustment layer and the driving voltage. It is supposed to be preferable that the film thickness of the cavity adjustment layer is within a range from 10 nm to 600 nm from the results shown in FIG. 3.

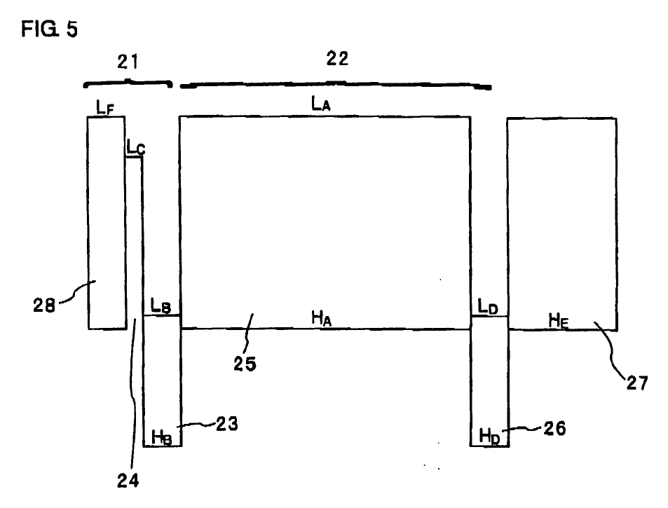

FIG. 4 is a cross-sectional view showing an organic EL display device of one example according to the invention. In the organic EL display layer, TFT (a thin film transistor) is used as an active element and drives the light emission in the respective pixels of R (red), G (green), and B (blue). With respect to FIG. 4, a channel region 11 comprising a polysilicon layer is formed on a transparent substrate of glass or the like, which is not illustrated. A drain electrode 12d and a source electrode 12s are formed on the channel region 11 and a gate electrode 14 is formed via a gate insulating film 13 between the drain electrode 12d and the source electrode 12s. An insulating layer 15 is formed on the gate electrode 14. The respective insulating layers are made of SiNₓ and/or SiO₂ etc.

A first leveling film 16 is formed on the drain electrode 12d and the source electrode 12s. A through hole part is formed on the first leveling film 16 on the drain electrode 12d and an anode 1 of an ITO film formed on the first leveling film 16 is introduced into the inside of the through hole part. A hole injecting layer 2 is formed on the anode 1 in a pixel region. A second leveling film 17 is formed in the portion other than the pixel region.

A cavity adjustment layer 3 and an electron extracting layer 4 are formed on the hole injecting layer 2 according to the invention. The cavity adjustment layer 3 and the electron extracting layer 4 are shown as a single layer in FIG. 4. As shown in FIG. 4, the cavity adjustment layer 3 and the electron extracting layer 4 are formed independently for the respective pixels of RGB. That is because the respective pixels of RGB are different in the optimum film thickness of the cavity adjustment layer and therefore, it is preferable to form the layers independently for the respective pixels of RGB. On the cavity adjustment layer 3 and the electron extracting layer 4 of each pixel, a first light emitting unit 5, an intermediate unit 6, and a second light emitting unit 7 are formed respectively for each pixel. An electron transporting layer 8 is formed on the second light emitting unit 7. The electron transporting layer 8 is so formed as to bury the gaps between the cavity adjustment layer 3, the electron extracting layer 4, the first light emitting unit 5, the intermediate unit independently on each pixel.

An electron injecting layer 9 and a cathode 10 are formed on the electron transporting layer 8. In FIG. 4, the electron injecting layer 9 and the cathode 10 are illustrated as a single layer. A protection layer 18 is formed on the cathode 10.

As shown in FIG. 4, the film thickness of the cavity adjustment layer 3 formed for each pixel is properly adjusted, so that the cavity in each pixel can be adjusted.

Although Example shown in FIG. 4 is a bottom emission type organic EL display device in which light is emitted toward the substrate side, the organic EL display device may be a top emission type organic EL display device in which the light is emitted to the side opposed to the substrate by reversing the positions of the anode 2 and the cathode 10 upside down and successively layering the electron injecting layer 9, the electron transporting layer 8, the second light emitting unit 7, the intermediate unit 6, the first light emitting unit 5, the electron extracting layer 4, and the cavity adjustment layer 3 on the cathode 10.

Further, in the organic EL display device shown in FIG. 4, the pixel region is formed to make the device be a display device, however the light emitting layer may be formed in the entire body to make the organic EL display device as a back light source.

### SECOND ASPECT OF THE INVENTION

FIG. 5 is a drawing schematically showing the energy levels of HOMO and LUMO of the respective layers composing the intermediate unit and the cavity adjustment unit in the organic EL element of Example according to the invention. In this Example, an intermediate unit 21 comprises a first electron extracting layer 23, an electron injecting layer 24, and an electron transporting layer 28. A cavity adjustment unit 22 comprises a first cavity adjustment layer 25 and a second electron extracting layer 26. An electron supply layer 27 is formed in the cathode side of the second electron extracting layer 26.

In FIG. 5, LUMO of the first electron extracting layer 23 is shown as L_{B}, and HOMO is shown as H_{B}. Also, LUMO of the electron injecting layer 24 is shown as L_{C} and LUMO of the electron transporting layer 28 is shown as L_{F} and LUMO of the first cavity adjustment layer 25 is shown as L_{A}, and HOMO is shown as H_{A}. Also, LUMO of the second electron extracting layer 26 is shown as L_{D}, and HOMO is shown as H_{D} and HOMO of the electron supply layer 27 is shown as H_{E}.

With respect to FIG. 5, in the organic E_{L} element according to the invention, the difference of the absolute values of L_{B} of the first electron extracting layer and HA of the first cavity adjustment layer 25 is 1.5 eV or lower. Accordingly, the first electron extracting layer 23 can easily extract an electron from the first cavity adjustment layer 25. The absolute value of L_{C} of the electron injecting layer 24 is smaller than the absolute value of L_{B} of the first electron extracting layer 23 and the absolute value of L_{F} of the electron transporting layer 28 is smaller than the absolute value of L_{C}. Accordingly, an electron extracted by the first electron extracting layer 23 is supplied to the anode side via the electron injecting layer 24 and the electron transporting layer 28.

The difference of the absolute values of L_{D} of the second electron extracting layer 26 and H_{E} of the electron supply layer 27 is 1.5 eV or lower in the present invention. Accordingly, the second electron extracting layer 26 can easily extract an electron from the electron supply layer 27. Since the absolute value of L_{A} of the first cavity adjustment layer is smaller than the absolute value of L_{D} of the second electron extracting layer 26, an electron extracted by the second electron extracting layer 26 is blocked by the first cavity adjustment layer 25 and accumulated in the second electron extracting layer 26. Accordingly, a high electric field is locally applied to strain the energy level and therefore, the driving electric current can be lowered.

In the electron supply layer 27 from which the electron is extracted, a hole is generated and the hole is supplied to the cathode side.

In the invention, as described above, an electron is supplied to the anode side from the intermediate unit 21 and the cavity adjustment unit 22 and at the same time a hole is supplied to the cathode side. Accordingly, light is efficiently emitted from the light emitting unit positioned in the anode side and the light emitting unit positioned in the cathode side, respectively. Also, as described above, since a high electric field is applied locally, the driving voltage can be lowered and even if the film thickness of the first cavity adjustment layer 25 is made thick, increase of the driving voltage can be suppressed.

Further, since supply of electrons in an excess quantity to the anode side by the first cavity adjustment layer 25 can be suppressed, the life property of the element can be improved and the reliability can be increased.

### EXAMPLES 8 to 16 AND COMPARATIVE EXAMPLES 1 TO 6

Organic EL elements of Examples 8 to 16 and Comparative Examples 1 to 6 respectively comprising a hole injecting layer, a hole transporting layer, a second light emitting unit, an intermediate unit, a cavity adjustment unit, a first light emitting unit, an electron transporting layer, and a cathode as shown in Table 3 were fabricated. The numbers in the parentheses in the following tables show the thickness (nm) of the respective layers.

As a substrate, a glass substrate on which an ITO (indium tin oxide) film as an anode is formed was used. The hole injecting layer was formed by forming a fluorocarbon (CFₓ) layer on the ITO film. In Table 3, (15 s) means the film formation time (second).

The respective layers shown in Table 3 were successively formed on the hole injecting layer formed as described above by vapor deposition method.

The hole transporting layer was formed by layering a HAT-CN6 layer on the NPB layer.

Each of the first light emitting unit and the second light emitting unit was a white-emitting unit formed by layering a blue emitting layer formed on an orange emitting layer. The orange emitting layer was positioned in the anode side and the blue emitting layer is positioned in the cathode side. In Table, % means % by weight unless otherwise specified.

The orange emitting layer and the blue emitting layer were deposited on the hole transporting layer formed as described above.

The orange emitting layer was formed using NPB as a hole transporting host material, TBADN as an electron transporting host material, and DBzR as a dopant material. The blue emitting layer was formed using TBADN as an electron transporting host material, NPB as a hole transporting host material, and TBP as a dopant material.

In Example 13, Example 14, and Comparative Example 5, the first light emitting unit and the second light emitting unit were formed respectively in form of a single white emitting layer. Accordingly, the DBzR as an orange emitting dopant and TBP as a blue emitting dopant were contained in one layer. Additionally, a NPB layer was formed in the anode side in the first light emitting unit and the second light emitting unit.

An electron transporting material may be used for the electron transporting layer of the intermediate unit and in Examples and Comparative Examples shown in Table 3, BCP is used. LUMO of BCP is −2.7 eV. The film thickness of the electron transporting layer in the intermediate unit is preferably in a range from 1 to 100 nm.

For the electron injecting layer of the intermediate unit, alkali metals, alkaline earth metals, their oxides and the like can be used. In Examples and Comparative Examples shown in Table 3, Li₂O, Li or Mg is used. The work function of Li is 2.9 eV and the work function of Mg is 3.9 eV. In the case of a metal oxide such as Li₂O, the work function of the metal such as Li may be within the range defined according to the invention. The film thickness of the electron injecting layer is preferably in a range from 0.1 to 10 nm.

For the first electron extracting layer of the intermediate unit, HAT-CN6 is used. LUMO of HAT-CN6 is −4.4 eV and HOMO is −7.0 eV. The film thickness of the first electron extracting layer is preferably in a range from 1 to 150 nm.

In Comparative Example 4, a V₂O₅ layer is used in place of the first electron extracting layer.

For the first cavity adjustment layer of the cavity adjustment unit, NPB is used. LUMO of NPB is −2.6 eV and HOMO is −5.4 eV.

For the second electron extracting layer of the cavity adjustment unit, HAT-CN6 is used. The film thickness of the second electron extracting layer is preferably in a range from 1 to 150 nm.

As the electron transporting layer formed on the first light emitting unit, an electron transporting layer having a layered structure of an Alq layer and a BCP layer is formed. In Example 13, Example 14 and Comparative Example 5, the electron transporting layer is formed in form of a BCP layer alone.

A cathode having a layered structure of a Li₂O layer and an Al layer is formed on the electron transporting layer.

Alq is tris-(8-quinolinato)aluminum(III) and has the following structure.

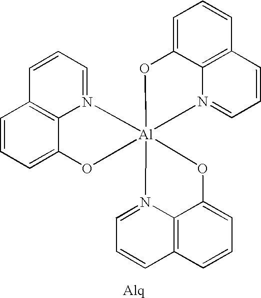

TABLE 3

| | Hole | Hole | | | Cavity | | Electron | |
|---|---|---|---|---|---|---|---|---|
| | Injecting | Transporting | Second Light | Intermediate | Adjustment | First Light | Transporting | |
| | Layer | layer | Emitting Unit | Unit | Unit | Emitting Unit | Layer | Cathode |
| Ex. 8 | CFx | NPB/HAT-CN6 | 70% NPB + 30% | BCP/Li₂O/ | NPB(60)/ | 70% NPB + 30% | Alq/BCP | Li₂O/Al |
| Comp. | (15 s) | (60)/(10) | TBADN + 3% | HAT-CN6 | HAT-CN6(5) | TBADN + | (3)/(10) | (3)/(200) |
| Ex. 1 | | | DBzR (60)/90% | (15)/(3)/(20) | | 3% DBzR(60)/ | | |
| Comp. | | | TBADN + 10% | | Alq(60)/ | 90% TBADN + | | |
| Ex. 2 | | | NPB + 2.5% | | HAT-CN6(5) | 10% NPB + | | |
| | | | TBP (50) | | | 2.5% TBP(50) | | |
| Ex. 9 | CFx | NPB/HAT-CN6 | 70% NPB + 30% | BCP/Li₂O/ | NPB(200)/HAT- | 70% NPB + 30% | Alq/BCP | Li₂O/Al |
| | (15 s) | (60)/(10) | TBADN + 3% | HAT-CN6 | CN6(5) | TBADN + 3% | (3)/(10) | (3)/(200) |
| Ex. 10 | | | DBzR (60)/90% | (15)/(3)/(20) | NPB/HAT-CN6/ | DBzR(60)/90% | | |
| | | | TBADN + 10% | | NPB/HAT-CN6 | TBADN + 10% | | |
| | | | NPB + 2.5% | | (100)/(5)/ | NPB + 2.5% | | |
| | | | TBP (50) | | (100)/(5) | TBP(50) | | |
| Comp. | | | | | NPB (200) | | | |
| Ex. 3 | | | | | | | | |
| Ex. 11 | CFx | NPB/HAT-CN6 | 70% NPB + 30% | BCP/Li₂O/ | NPB/HAT-CN6 | 70% NPB + 30% | Alq/BCP | Li₂O/Al |
| | (15 s) | (60)/(10) | TBADN + 3% | HAT-CN6 | (500)/(5) | TBADN + 3% | (3)/(10) | (3)/(200) |
| Ex. 12 | | NPB/HAT-CN6 | DBzR (60)/90% | (15)/(3)/(20) | NPB/HAT-CN6 | DBzR(60)/90% | | |
| | | (60)/(10) | TBADN + 10% | | (550)/(5) | TBADN + 10% | | |
| Comp. | | NPB (60) | NPB + 2.5% | BCP/Mg/V₂0₅ | NPB/V₂0₅ | NPB + 2.5% | | Mg/Al |
| Ex. 4 | | | TBP (50) | (15)/(1)/(20) | (60)/(5) | TBP(50) | | (1)/(200) |
| Ex. 13 | CFx | NPB/HAT-CN6 | NPB(60)/80% | BCP/Li₂O/ | NPB/HAT-CN6/ | NPB(60)/80% | BCP (10) | Li₂O/Al |
| | (15 s) | (60)/(10) | TBADN + 20% | HAT-CN6 | NPB/HAT-CN6/ | TBADN + 20% | | (3)/(200) |
| | | | NPB + 2.5% | (15)/(3)/(20) | NPB/HAT-CN6 | NPB + 2.5% | | |
| | | | TBP + 0.2% | | (60)/(5)/(60)/ | TBP + 0.2% | | |
| | | | DBzR(50) | | (5)/(60)/(5) | DBzR(50) | | |
| Ex. 14 | | | | | NPB/HAT-CN6 | | | |
| | | | | | (180)/(5) | | | |
| Comp. | | | | | NPB(180) | | | |
| Ex. 5 | | | | | | | | |
| Ex. 15 | CFx | NPB/HAT-CN6 | 70% NPB + | BCP/Li/HAT-CN6 | NPB/HAT-CN6/ | 70% NPB + | Alq/BCP | Li₂O/Al |
| | (15 s) | (60)/(10) | 30% TBADN + | (15)/(1)/(20) | NPB/HAT-CN6 | 30% TBADN + | (3)/(10) | (3)/(200) |
| | | | 3% DBzR(60)/ | | (100)/(5)/ | 3% DBzR(60)/ | | |
| | | | 90% TBADN + | | (100)/(5) | 90% TBADN + | | |
| Ex. 16 | | | 10% NPB + | | NPB/HAT-CN6 | 10% NPB + | | |
| | | | 2.5% TBP (50) | | (200)/(5) | 2.5% TBP(50) | | |
| Comp. | | | | | NPB(200) | | | |
| Ex. 6 | | | | | | | | |

[Evaluation of Organic EL Element]

Each organic EL element fabricated in the above-mentioned manner was subjected to measurement of the driving voltage, light emitting efficiency, and brightness half life. The measurement results are shown in Table 4. The measurement results are the values at driving electric current of 40 mA/cm².

TABLE 4

| | | Light Emitting | |
|---|---|---|---|
| | Driving | Efficiency | Brightness |
| | Voltage (V) | (cd/A) | Half Life |
| EX. 8 | 10.8 | 23.8 | 500 |
| Comp. Ex. 1 | 10.5 | 33.2 | 400 |
| Comp. Ex. 2 | Not Less than 20 | 25.6 | 50 |
| EX. 9 | 13.4 | 24.2 | 700 |
| EX. 10 | 12.7 | 24.3 | 750 |
| Comp. Ex. 3 | 13.7 | 25.2 | 650 |
| EX. 11 | 15.6 | 20.2 | 400 |
| EX. 12 | 16 | 19.8 | 370 |
| Comp. Ex. 4 | 15.6 | 14.7 | 30 |
| EX. 13 | 9.7 | 25.8 | 500 |
| EX. 14 | 10.5 | 22.6 | 450 |
| Comp. Ex. 5 | 11.1 | 23.4 | 300 |
| EX. 15 | 12.7 | 24.3 | 700 |
| EX. 16 | 13.4 | 24.2 | 680 |
| Comp. Ex. 6 | 13.7 | 25.2 | 600 |

As being made clear from the results shown in Table 4, it is found that in Examples 8 to 16 according to the invention, the driving voltage is low, the light emitting efficiency is good, and the brightness half life is long.

In comparison of Example 8 comprising the cavity adjustment unit with Comparative Example 1 comprising no cavity adjustment unit, although Example 8 was slightly inferior to Comparative Example 1 in the light emitting efficiency, it could be driven at approximately same driving voltage and the brightness half life of Example 8 was longer than that of Comparative Example 1. Accordingly, the cavity adjustment unit could be installed to adjust the cavity without increasing the driving voltage or without deteriorating the life property.

With respect to Comparative Example 2 comprising the cavity adjustment unit in which NPB was replaced with Alq, the driving voltage was considerably increased and the brightness half life was significantly shortened.

With respect to Comparative Example 4 comprising the cavity adjustment unit in which HAT-CN6 was replaced with V₂O₅, the light emitting efficiency was decreased and the brightness half life was significantly shortened.

As being made clear by comparison of Examples 13 and 14 with Comparative Example 5 and comparison of Examples 15 and 16 with Comparative Example 6, it is found that in the case where the film thickness of the total of the NPB layer is considerably made thick, the driving voltage can be lowered by inserting the HAT-CN6 layer, which is a first electron extracting layer, is inserted at appropriate intervals into a plurality of layers.

[Organic EL Display Device]

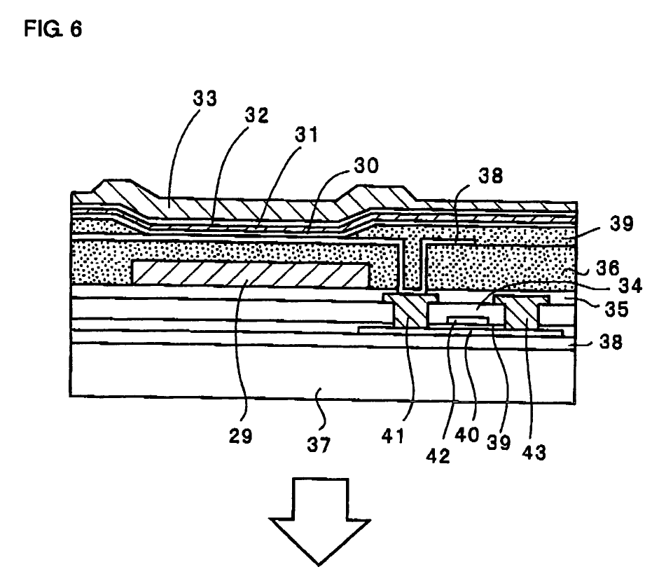

FIG. 6 shows a cross-sectional view showing a bottom emission type organic EL display device of an example according to the invention. In the organic EL display device, TFT is used as an active element for emitting light in each pixel. A diode or the like may be used also as the active element. In the organic EL display device, a color filter is installed. The organic EL display device is a bottom emission type display device for display by emitting light downward via the substrate 17 shown as an arrow.

With respect to FIG. 6, a first insulating layer 38 is formed on a substrate 37, which is a transparent substrate of glass or the like. The first insulating layer 38 is formed using SiO₂, SiNₓ and the like. A channel region 40 comprising a polysilicon layer is formed on the first insulating layer 38. A drain electrode 41 and a source electrode 43 are formed on the channel region 40 and a gate electrode 42 is formed via a second insulating layer 39 between the drain electrode 41 and the source electrode 42. A third insulating layer 34 is formed on the gate electrode 42. The second insulating layer 39 is formed using, for example, SiO₂ and SiNₓ. The third insulating layer 34 is formed using SiO₂ and SiNₓ.

A fourth insulating layer 35 is formed on the third insulating layer 34. The fourth insulating layer 35 is formed using, for example SiNₓ. A color filter layer 29 is formed on the portion of a pixel region on the fourth insulating layer 35. As the color filter layer 29, a color filter of R (red), G (green), or B (blue) may be formed. A first leveling film 36 is formed on the color filter layer 29. A through hole part is formed on the first leveling film 36 on the drain electrode 41 and a hole injecting electrode 38 of ITO (indium tin oxide) formed on the first leveling film 36 is introduced into the inside of the through hole part. A hole injecting-transporting unit 30 is formed on the hole injecting electrode (anode) 38 in the pixel region. A second leveling film 39 is formed in the portion other than the pixel region.

In the layered light emitting unit 31 is formed on the hole injecting-transporting layer 30. The layered light emitting unit 31 has a structure, according to the invention, comprising an intermediate unit and a cavity adjustment unit between the first light emitting unit and the second light emitting unit. An electron transporting layer 32 is formed on the layered light emitting unit 31 and an electron injecting electrode (cathode) 33 is formed on the electron transporting layer 32.

As described above, with respect to the organic EL element of this example, the organic EL element is composed by layering the hole injecting electrode (anode) 28, the hole injecting-transporting unit 30, the layered light emitting unit 31, an electron transporting layer 32, and an electron injecting electrode (cathode) 33 on the pixel region.

In the layered light emitting unit 31 of this example, since a light emitting units comprising an orange emitting layer and a blue emitting layer layered on each other is used, white light is emitted from the layered light emitting unit 31. The white light is emitted through the substrate 37 to outside, and since the color filter layer 29 is formed in the light emission side, R, G, or B color light is emitted depending on the color of the color filter layer 29. In the case of an element emitting monochromic light, the color filter layer 29 is not necessarily required.

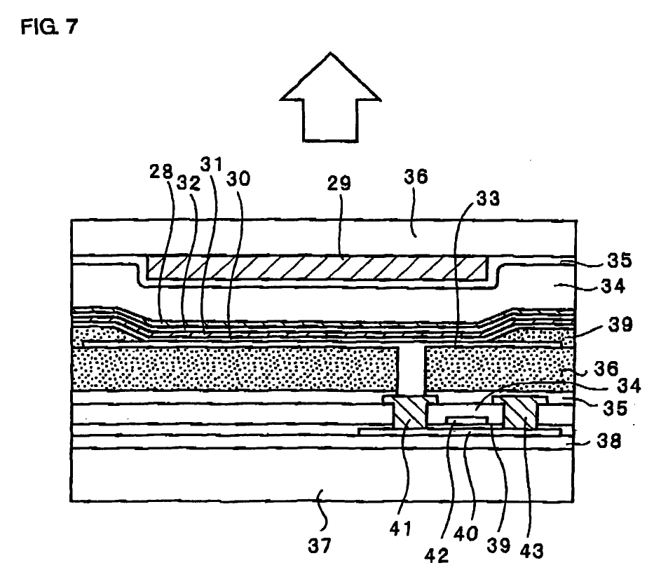

FIG. 7 is a cross-sectional view of a top emission type organic EL display device of one example according to the invention. The organic EL display device of the example is a top emission type organic EL display device for display by emitting light upward through a substrate 37 as shown as an arrow.

The portion from the substrate 37 to the anode 38 is fabricated approximately same as the example shown in FIG. 6. However, the color filter layer 29 is not formed on the fourth insulating layer 35 but formed on the upper part of the organic EL element. Practically, the color filter layer 29 is installed on a transparent sealing substrate 36 of glass or the like and an overcoat layer 35 is coated thereon and the resulting body is stuck to the anode 38 via a transparent adhesive layer 34. Further, in this example, the positions of the anode and the cathode are reversed to those of the example shown in FIG. 6.

As the anode 38, a transparent electrode is formed and for example, it is formed by layering ITO with a film thickness of about 100 nm and silver with a film thickness of about 20 nm. As the cathode 33, a reflective electrode is formed and for example, it is formed by forming a thin film of aluminum, chromium, or silver in a film thickness about 100 nm. The overcoat layer 35 is formed using an acrylic resin or the like in a film thickness of about 1 μm. The color filter layer 29 may be a pigment type or a dye type and the thickness is about 1 μm.

The white color light emitted from the layered light emitting unit 31 is emitted outside through the sealing substrate 36, however since the color filter layer 29 is formed in the light emitting side, R, G, or B color light is emitted in accordance with the color of the color filter layer 29. Since the organic EL display device of this example is top emission type, even the region where the thin film transistor is installed can be used as a pixel region and the color filter layer 29 is formed in a wider range than that in the example shown in FIG. 6. According to this example, a wider region can be used as the pixel region and the aperture ratio can be increased. Further, formation of the light emitting layers having a plurality of light emitting units can be carried out without being affected by the active matrix and therefore, the option of the designing can be increased.

Although a glass plate is used as the sealing substrate in this example, the sealing substrate in the invention is not limited to the glass plate and a film-like material such as an oxide film of, for example, SiO₂ and a nitride film such as SiNₓ can be used as the sealing substrate. In this case, the film-like sealing substrate can be formed directly on the element and therefore, it is no need to form an transparent adhesive layer.

### THIRD ASPECT OF THE INVENTION

[Simulation Result]

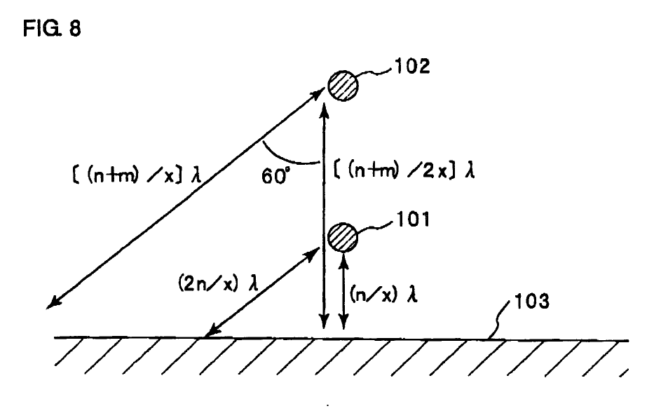

Table 5 shows the simulation results of the light emission intensity at various visible angles in the case where the optical distance between a light source 101 (the first light emitting layer) and the reflection surface 103 of the reflective electrode is kept constant to be (¼)λ and the optical distance between the light source 102 (the second light emitting layer) and the reflection surface 103 of the reflective electrode is changed in a range from ( 4/4)λ to (⅜)λ, as shown in FIG. 8. The light emission intensity is evaluated at four visible angles, the front (0°), 30°, 45°, and 60°. In Table 5, the relative values are shown in the case where the light emission intensity in the front direction is converted into 1. “Maximum /minimum” indicates the ratio of the maximum value/minimum value at these four visible angles. “Front intensity” indicates the relative intensity in the case where the light emission intensity in the front direction is converted into 1 in the light emission layer composed of a first light emission layer alone.

In Table 5, (2), (4), and (6) satisfied the conditions of the invention.

TABLE 5

| | | Optical | | | | | Maximum | |
|---|---|---|---|---|---|---|---|---|
| | | Distance to | | | | | Value/ | |
| | | the Reflective | | | | | Minimum | Front |
| | | Electrode | Front | 30° | 45° | 60° | Value | Intensity |
| Second | (1) | (4/4)λ | 1 | 1.65 | 0.44 | 0.12 | 13.9 | 1.07 |
| Light | (2) | (7/8)λ | 1 | 0.70 | 1.13 | 0.95 | 1.6 | 1.28 |
| Emitting | (3) | (3/4)λ | 1 | 0.54 | 0.35 | 0.07 | 13.7 | 2.05 |
| Layer | (4) | (5/8)λ | 1 | 1.00 | 0.30 | 0.63 | 3.4 | 1.90 |
| | (5) | (2/4)λ | 1 | 1.22 | 1.32 | 0.16 | 8.0 | 1.11 |
| | (6) | (3/8)λ | 1 | 0.80 | 0.61 | 1.16 | 2.0 | 1.21 |

| | | | | | | | |
|---|---|---|---|---|---|---|---|
| First Light Emitting | (1/4)λ | 1 | 0.78 | 0.34 | 0.11 | 8.9 | 1.00 |
| Layer alone | | | | | | | |

As shown in Table 5, in the case of (2), (4), and (6) satisfying the conditions of the invention, relatively high light emission intensity is obtained at any visible angle of 30°, 45°, and 60° and the ratio of the maximum value/minimum value is lower than those of other cases. Accordingly, it is found that the visible angle dependency is lowered.

Also being understood from Table 5, in the case where the first light emitting layer is formed alone, the light emission intensity is lowest at a visible angle of 60° and accordingly, the visible angle dependency can be decreased by setting the second light emitting layer to have high light emission intensity at 60°.

The optical distance is calculated from the film thickness of each layer and the refraction index and further a multi-mode has to be taken into consideration, however in this specification, it is calculated while the calculation of the refraction index of each layer and the multi-mode are simplified.

### EXAMPLE 17

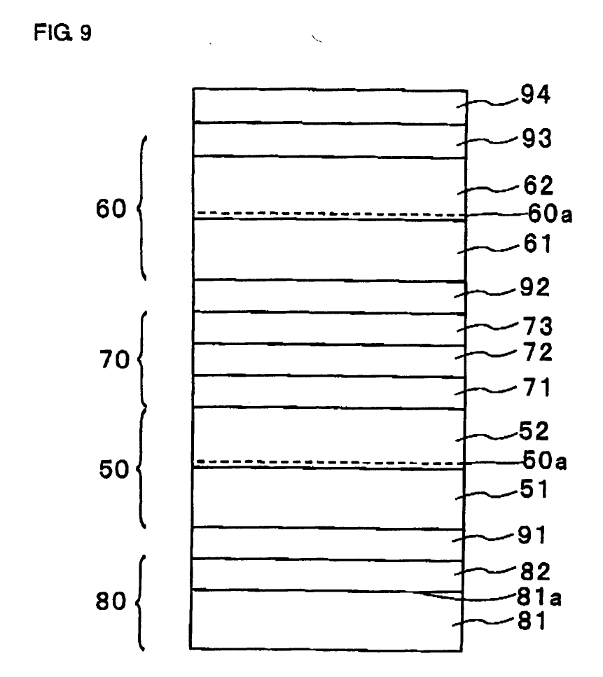

FIG. 9 is a schematic cross-sectional view showing an organic EL element fabricated in this example. In the organic EL element of this example, as shown in FIG. 9, a metal thin film 81 of Al is formed on a substrate, which is not illustrated and a transparent conductive film 82 (film thickness of 30 nm) of an ITO (indium tin oxide) film was formed thereon. A reflective electrode is composed of the transparent conductive film 82 and the metal thin film 81 and the upper surface of the metal thin film 81 is to be the reflection surface 41a.

A hole transporting layer 91 (film thickness of 30 nm) of NPB is formed on the transparent conductive film 82. The hole transporting layer 91 works as a first cavity adjustment layer.

An orange emitting layer 51 (film thickness of 60 nm) and a blue emitting layer 52 (film thickness of 50 nm) are layered in this order on the hole transporting layer 91. The first light emitting layer 50 is a white emitting layer composed of the orange emitting layer 51 and the blue emitting layer 52. The light emitting position 50a of the first light emitting layer 50 is in the region at 5 nm from the interface of the orange emitting layer 51 and the blue emitting layer 52 to the blue emitting layer side.

The orange emitting layer 51 is formed using 100% by weight of NPB, a hole transporting material, as a host material and DBzR, which is an orange emitting dopant in an amount of 3% by weight to 100% by weight of NPB.

The blue emitting layer 52 is formed using 100% by weight of TBADN, an electron transporting material, as a host material and TBP, which is a blue emitting dopant in an amount of 1% by weight to 100% by weight of TBADN.

An electron transporting layer 71 (film thickness of 20 nm), an electron injecting layer 72 (film thickness of 10 nm), and an electron extracting layer 73 (film thickness of 20 nm) are layered in this order on the first light emitting layer 50. The intermediate unit 70 is composed of the electron transporting layer 71, the electron injecting layer 72, and the electron extracting layer 73. The electron transporting layer 71 is formed using Alq. The electron injecting layer 72 is formed by depositing Li, however it is very thin, it is formed in form of a composite of Alq of the electron transporting layer 71 supposed to have a composition of Alq:Li=1:1. The electron extracting layer 73 is formed using HAT-CN6.

A second cavity adjustment layer 92 (film thickness of 275 nm) is formed on the intermediate unit 70. The second cavity adjustment layer 92 is also formed using NPB.

An orange emitting layer 61 and a blue emitting layer 62 are layered and formed in this order on the second cavity adjustment layer 92. The second light emitting layer 60 is composed of the orange emitting layer 61 and the blue emitting layer 62. The orange emitting layer 61 and the blue emitting layer 62 are formed in the same manner as the orange emitting layer 51 and the blue emitting layer 52 of the first light emitting layer 50.

The light emitting position 60a of the second light emitting layer 60 is in the region at 5 nm from the interface of the orange emitting layer 61 and the blue emitting layer 62 to the blue emitting layer 62 side.

An electron transporting layer 93 (film thickness of 20 nm) is formed on the second light emitting layer 60. The electron transporting layer 93 is formed using Alq.

A metal thin film electrode 94 (Li film thickness 1 nm:Ag film thickness 15 nm) of Li/Ag, which is a light emitting side electrode, is formed on the electron transporting layer 93.

The optical distance between the light emitting position of the first light emitting layer and the reflection surface of the reflective electrode and the optical distance between the light emitting position of the second light emitting layer and the reflection surface of the reflective electrode can be adjusted by adjusting the film thickness of the first cavity adjustment layer 91. Also, the optical distance between the light emitting position of the second light emitting layer and the reflection surface of the reflective electrode can be adjusted by adjusting the film thickness of the second cavity adjustment layer 92.

In the organic EL element fabricated as described above, the optical distance between the light emitting position 50a of the first light emitting layer 50 and the reflection surface 91a of the reflective electrode is 125 nm. Also, the optical distance between the light emitting position 60a of the second light emitting layer 60 and the reflection surface 81a of the reflective electrode 80 is 312.5 nm.

Each of the first light emitting layer 50 and the second light emitting layer 60 in this example was formed to be a white emitting layer by layering an orange emitting layer and a blue emitting layer and the mean wavelength λ of light to be emitted is 500 nm. Accordingly, the optical distance of the light emitting position of the first light emitting layer and the reflection surface of the reflective electrode is set to be (¼)λ and the optical distance between the light emitting position of the second light emitting layer and the reflection surface of the reflective electrode is set to be (⅝)λ. As a result, these distances are set within the range of the invention.

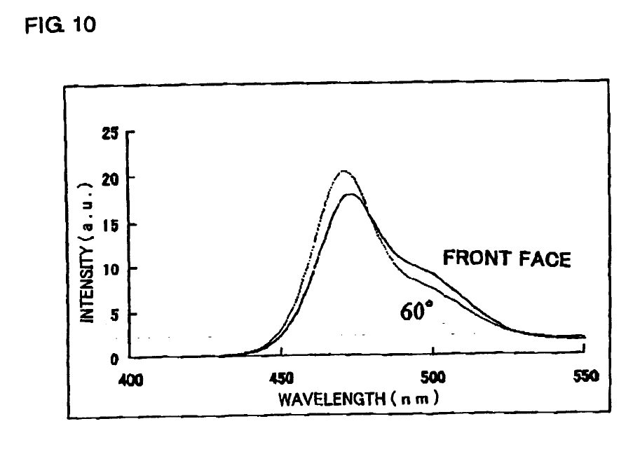

FIG. 10 is a graph showing a spectrum in the front direction and a spectrum at a visible angle of 60° of the organic EL element shown in FIG. 9. As shown in FIG. 10, the light emission intensity in the front direction and the light emission intensity in the direction at a visible angle of 60° are almost same and thus it is understood that the visible angle dependency is lowered. In the case where the light emission intensity with wavelength of 500 nm in the front direction is defined as 100, the light emission intensity in the direction at a visible angle of 60° is 83.

### COMPARATIVE EXAMPLE 7

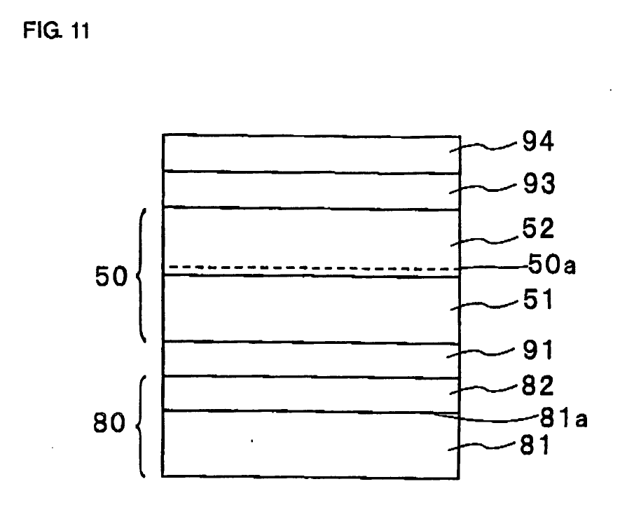

FIG. 11 is a schematic cross-sectional view showing a structure of an organic EL element of Comparative Example 7. Similarly to Example 17, a metal thin film 41 is formed on a substrate and a transparent conductive film 42 is formed on the metal thin film 41. A hole transporting layer 51 is formed on the transparent conductive film 42. An orange emitting layer 11 and a blue emitting layer 12 are formed on the hole transporting layer 51. An electron transporting layer 53 is formed on the blue emitting layer 12. As a light outputting electrode, a metal thin film 54 of Ag is formed on the electron transporting layer 53.

The organic EL element of Comparative Example 7 comprised only one light emitting layer and a first light emitting layer 10 alone is formed. The optical distance between the light emitting position 10a of the first light emitting layer 10 and the reflection surface 41a of the reflective electrode 40 was 125 nm.

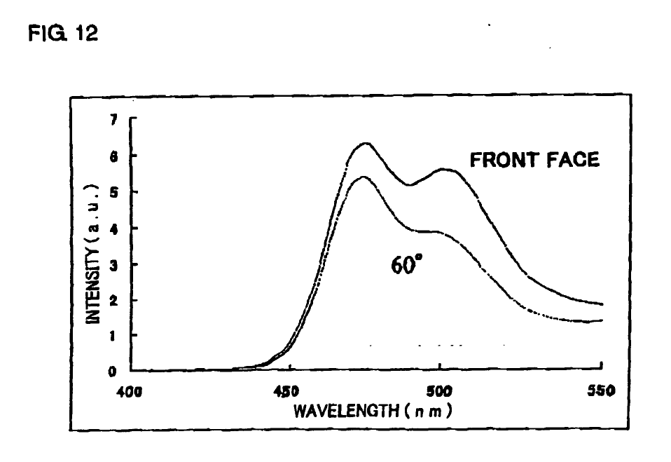

FIG. 12 is a graph showing a spectrum in the front direction and a spectrum at a visible angle of 60° of the organic EL element of Comparative Example 7. As being made clear in FIG. 12, the light emission intensity in the front direction and the light emission intensity in the direction at a visible angle of 60° are considerable different. For example, in the case where the light emission intensity with wavelength of 500 nm in the front direction is defined as 100, the light emission intensity in the direction at a visible angle of 60° is 68 and it is understood that the visible angle dependency is significant.

### COMPARATIVE EXAMPLE 8

With the same structure of Example 17 shown in FIG. 9, an organic EL element in which the distance between the light emitting position 20a of the second light emitting layer 20 and the reflection surface 41a of the reflective electrode 40 was changed to be 375 nm was fabricated. The distance 375 nm is equivalent to (¾)λ in the case where the wavelength λ is 500 nm. In the case the light emission intensity of Comparative Example 8 with wavelength of 500 nm in the front direction is defined as 100, the light emission intensity in the direction at a visible angle of 60° is 64. Accordingly, it is understood that the visible angle dependency is significant high as compared with that of Example 17.

As described above, it is made clear that the organic EL element of Example 17 which was designed according to the invention can be provided with significantly decreased visible angle dependency as compared with the organic EL elements of Comparative Example 7 and Comparative Example 8.

What is claimed is:

1. An organic electroluminescent element comprising a cathode, an anode, and a plurality of light emitting units arranged between the cathode and the anode via an intermediate unit, wherein the organic electroluminescent element is further provided with a cavity adjustment layer for adjusting the optical distance from the light emitting positions of the respective light emitting units to the anode and an electron extracting layer formed adjacent to the cavity adjustment layer in a light emitting unit side between the light emitting unit nearest to the anode and the anode.

2. The organic electroluminescent element according to claim 1, wherein the cavity adjustment layer is formed using a hole transporting material.

3. The organic electroluminescent element according to claim 2, wherein the cavity adjustment layer is formed using an arylamine type hole transporting material.

4. The organic electroluminescent element according to claim 1, wherein a second electron extracting layer is formed adjacently to the cavity adjustment layer in the anode side.

5. The organic electroluminescent element according to claim 1, wherein the electron extracting layer is formed using a pyrazine derivative defined by the following structural formula: 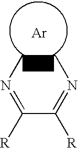
wherein Ar denotes an aryl group; R denotes hydrogen; an alkyl, an alkyloxy, or an dialkylamine group having 1 to 10 carbon atoms; or F, Cl, Br, I, or CN.

6. The organic electroluminescent element according to claim 1, wherein the electron extracting layer is formed using a hexaazatriphenylene derivative defined by the following structural formula: 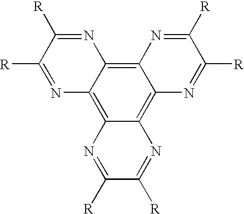
wherein R denotes hydrogen; an alkyl, an alkyloxy, or an dialkylamine group having 1 to 10 carbon atoms; or F, Cl, Br, I, or CN.

7. A bottom emission-type organic electroluminescent display device comprising organic electroluminescent elements each having an element structure sandwiched between an anode and a cathode, and an active matrix driving substrate having each active element for supplying a display signal for each display pixel to the organic electroluminescent elements, in which each organic electroluminescent element is provided on the active matrix driving substrate and, between the cathode and the anode, an electrode provided on the substrate side is a transparent electrode; wherein each of the organic electroluminescent element is the organic electroluminescent element according to claim 1.

8. The organic electroluminescent display device according to claim 7, wherein each organic electroluminescent element is a white emitting element and a color filter is arranged between the organic electroluminescent element and the substrate.

9. A top emission-type organic electroluminescent display device comprising organic electroluminescent elements each having an element structure sandwiched between an anode and a cathode, an active matrix driving substrate having each active element for supplying a display signal for each display pixel to the organic electroluminescent elements, and a transparent sealing substrate provided opposite to the active matrix driving substrate, in which each organic electroluminescent element is arranged between the active matrix driving substrate and the sealing substrate and, between the cathode and the anode, the electrode provided on a sealing substrate side is a transparent electrode; wherein each of the organic electroluminescent element is the organic electroluminescent element according to claim 1.

10. The organic electroluminescent display device according to claim 9, wherein each organic electroluminescent element is a white emitting element and a color filter is arranged between the organic electroluminescent element and the sealing substrate.

11. An organic electroluminescent device comprising the organic electroluminescent element according to claim 1.

12. An organic electroluminescent element comprising a cathode, an anode, an intermediate unit arranged between the cathode and the anode, a first light emitting unit arranged between the cathode and the intermediate unit, a second light emitting unit arranged between the anode and the intermediate unit, and a cavity adjustment unit arranged between the intermediate unit and the second light emitting unit, while adjoining the intermediate unit, wherein
the intermediate unit comprises a first electron extracting layer for extracting an electron from the cavity adjustment unit and an electron injecting layer adjoining the anode side of the first electron extracting layer:
the cavity adjustment unit is formed adjoining the cathode side of the first electron extracting layer and comprises a first cavity adjustment layer from which an electron is extracted by the first electron extracting layer and a second electron extracting layer for extracting an electron from an electron supply layer adjoining the cathode side:
the absolute value of an energy level |LUMO (B)| of the lowest unoccupied molecular orbital (LUMO) of the first electron extracting layer and the absolute value of an energy level |HOMO (A)| of the highest occupied molecular orbital (HOMO) of the first cavity adjustment layer are in the relationship of |HOMO (A)|−|LUMO (B)|≦1.5 eV and the absolute value of an energy level |LUMO (C)| of the lowest unoccupied molecular orbital (LUMO) or the absolute value of the work function |WF (C)| of the electron injecting layer is lower than |LUMO (B)|: and the absolute value of an energy level |LUMO (D)| of the lowest unoccupied molecular orbital (LUMO) of the second electron extracting layer and the absolute value of an energy level |HOMO (E)| of the highest occupied molecular orbital (HOMO) of the electron supply layer are in the relationship of |HOMO (E)|−|LUMO (D)|≦1.5 eV and the absolute value of an energy level |LUMO (A)| of the lowest unoccupied molecular orbital (LUMO) of the first cavity adjustment layer and |LUMO (D)| are in the relationship of |LUMO (A)|≦|LUMO (D)|.

13. The organic electroluminescent element according to claim 12, wherein the electron supply layer is formed in the first light emitting unit.

14. The organic electroluminescent element according to claim 12, wherein the electron supply layer is a second cavity adjustment layer formed in the cavity adjustment unit.

15. The organic electroluminescent element according to claim 12, wherein the first and the second cavity adjustment layers are formed using a hole transporting material.

16. The organic electroluminescent element according to claim 15, wherein the hole transporting material is a tertiary arylamine type material.

17. The organic electroluminescent element according to claim 12, wherein the cavity adjustment unit comprises a plurality of repeating units of the first cavity adjustment layer and the second electron extracting layer.

18. The organic electroluminescent element according to claim 12, wherein an electron transporting layer is formed between the electron injecting layer of the intermediate unit and the second light emitting unit and the absolute value of an energy level |LUMO (F)| of the lowest unoccupied molecular orbital (LUMO) of the electron transporting layer is lower than the |LUMO (C)| or the |WF (C)|.

19. The organic electroluminescent element according to claim 12, wherein the first and/or the second electron extracting layer is formed using a pyrazine derivative defined by the following structural formula: 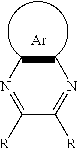
wherein Ar denotes an aryl group; R denotes hydrogen; an alkyl, an alkyloxy, or an dialkylamine group having 1 to 10 carbon atoms; or F, Cl, Br, I, or CN.

20. The organic electroluminescent element according to claim 12, wherein the first and/or the second electron extracting layer is formed using a hexaazatriphenylene derivative defined by the following structural formula: 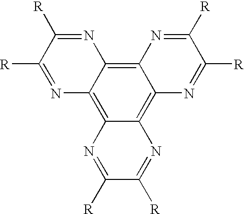
wherein R denotes hydrogen; an alkyl, an alkyloxy, or an dialkylamine group having 1 to 10 carbon atoms; or F, Cl, Br, I, or CN.

21. A bottom emission type organic electroluminescent display device comprising organic electroluminescent elements each having an element structure sandwiched between an anode and a cathode, and an active matrix driving substrate having each active element for supplying a display signal for each display pixel to the organic electroluminescent elements, in which each organic electroluminescent element is provided on the active matrix driving substrate and, between the cathode and the anode, an electrode provided on the substrate side is a transparent electrode, wherein each of the organic electroluminescent element is the organic electroluminescent element according to claim 12.

22. The organic electroluminescent display device according to claim 21, wherein each organic electroluminescent element is a white emitting element and a color filter is arranged between the organic electroluminescent element and the substrate.

23. A top emission type organic electroluminescent display device comprising organic electroluminescent elements each having an element structure sandwiched between an anode and a cathode, an active matrix driving substrate having each active element for supplying a display signal for each display pixel to the organic electroluminescent elements, and a transparent sealing substrate provided opposite to the active matrix driving substrate, in which each organic electroluminescent element is arranged between the active matrix driving substrate and the sealing substrate and, between the cathode and the anode, the electrode provided on a sealing substrate side is a transparent electrode, wherein each of the organic electroluminescent element is the organic electroluminescent element according to claim 12.

24. The organic electroluminescent display device according to claim 23, wherein each organic electroluminescent element is a white emitting element and a color filter is arranged between the organic electroluminescent element and the sealing substrate.

25. An organic electroluminescent device comprising the organic electroluminescent element according to claim 12.

26. An organic electroluminescent element comprising a reflective electrode, a light output side electrode, a first light emitting layer and a second light emitting layer arranged between the reflective electrode and the light output side electrode, wherein
the optical distance between the light emitting position of the first light emitting layer and the reflection face of the reflective electrode is (n/x)λ and the optical distance between the light emitting position of the second light emitting layer and the reflection face of the reflective electrode is [(n+m)/2x]]λ, wherein λ denotes the mean wavelength of a desired light emission; n is an odd number; m is an even number; and x is a natural number.

27. The organic electroluminescent element according to claim 26, wherein the first light emitting layer and the second light emitting layer are layered via an intermediate unit.

28. The organic electroluminescent element according to claim 27, wherein, in the case where the first light emitting layer is arranged between the reflective electrode and the intermediate unit and the second light emitting layer is arranged between the light output side electrode and the intermediate unit, a first cavity adjustment layer is formed between the reflective electrode and the first light emitting layer and the second cavity adjustment layer is formed between the intermediate unit and the second light emitting layer.

29. The organic electroluminescent element according to claim 27, wherein one between the reflective electrode and the light output side electrode is an anode and the other is a cathode:
the intermediate unit comprises an electron extracting layer formed in the cathode side, an electron injecting layer adjoining the anode side of the electron extracting layer, and an electron transporting layer adjoining the anode side of the electron injecting layer: and
the electron extracting layer extracts an electron from the adjacent layer adjoining the anode side and supplies the extracted electron to the anode side via the electron injecting layer and the electron transporting layer and at the same time a hole generated in the adjacent layer by the electron extraction is supplied to the cathode side.

30. The organic electroluminescent element according to claim 28, wherein the first cavity adjustment layer and/or the second cavity adjustment layer is formed using a hole transporting material.

31. The organic electroluminescent element according to claim 26, wherein each of the first light emitting layer and the second light emitting layer is a white emitting layer having a layered structure of an orange emitting layer and a blue emitting layer.

32. A bottom emission type organic electroluminescent display device comprising organic electroluminescent elements each having an element structure sandwiched between an anode and a cathode, and an active matrix driving substrate having each active element for supplying a display signal for each display pixel to the organic electroluminescent elements, in which each organic electroluminescent element is provided on the active matrix driving substrate and, between the cathode and the anode, an electrode provided on the substrate side is a transparent electrode, wherein each of the organic electroluminescent element is the organic electroluminescent element according to claim 26.

33. The organic electroluminescent display device according to claim 32, wherein each organic electroluminescent element is a white emitting element and a color filter is arranged between the organic electroluminescent element and the substrate.

34. A top emission type organic electroluminescent display device comprising organic electroluminescent elements each having an element structure sandwiched between an anode and a cathode, an active matrix driving substrate having each active element for supplying a display signal for each display pixel to the organic electroluminescent elements, and a transparent sealing substrate provided opposite to the active matrix driving substrate, in which each organic electroluminescent element is arranged between the active matrix driving substrate and the sealing substrate and, between the cathode and the anode, the electrode provided on a sealing substrate side is a transparent electrode, wherein each of the organic electroluminescent element is the organic electroluminescent element according to claim 26.

35. The organic electroluminescent display device according to claim 34, wherein each organic electroluminescent element is a white emitting element and a color filter is arranged between the organic electroluminescent element and the sealing substrate.

36. An organic electroluminescent device comprising the organic electroluminescent element according to claim 26.
